(19) United States
(12) Patent Application Publication
(10) Pub. No.: US 2025/0174265 A1
(43) Pub. Date: May 29, 2025

(54) VERTICAL MEMORY DEVICE

(71) Applicant: SK hynix Inc., Gyeonggi-do (KR)

(72) Inventors: Seung-Hwan KIM, Gyeonggi-do (KR); Seok Pyo SONG, Gyeonggi-do (KR)

(21) Appl. No.: 19/034,575

(22) Filed: Jan. 23, 2025

Related U.S. Application Data
(63) Continuation-in-part of application No. 18/542,769, filed on Dec. 18, 2023, now Pat. No. 12,230,313.
Application No. 18/542,769 is a continuation of application No. 17/739,944, filed on May 9, 2022, now Pat. No. 11,887,654.
Application No. 17/739,944 is a continuation of application No. 16/854,382, filed on Apr. 21, 2020, now Pat. No. 11,355,177.

(30) Foreign Application Priority Data
Jul. 12, 2019 (KR) 10-2019-0084689

(51) Int. Cl. G11C 11/408; H01L 23/528; H10B 12/00; H10D 1/68

(52) U.S. Cl. CPC G11C 11/4085; H01L 23/528; H10B 12/30; H10B 12/50; H10D 1/714

(57) ABSTRACT

A method of fabricating a semiconductor device includes forming a memory cell array stack including a vertical stack of pad portions over a first substrate, forming first bonding pads each coupled to a different one of the pad portions in the vertical stack, forming control circuits including a plurality of sub-word line drivers over a second substrate, forming multi-layer level metal wiring coupled to the sub-word line drivers, forming second bonding pads coupled to the multi-layer level metal wiring, and performing a wafer bonding process for electrical coupling between the memory cell array stack and the control circuits.

### CROSS-REFERENCE TO RELATED APPLICATIONS

The present application is a continuation-in-part application of U.S. patent application Ser. No. 18/542,769, filed on Dec. 18, 2023, which is a continuation application of U.S. patent application Ser. No. 17/739,944, filed on May 9, 2022 and issued as U.S. Pat. No. 11,887,654 on Jan. 30, 2024, which is a continuation application of U.S. patent application Ser. No. 16/854,382, filed on Apr. 21, 2020 and issued as U.S. Pat. No. 11,355,177 on Jun. 7, 2022, and claims priority of Korean Patent Application No. 10-2019-0084689, filed on Jul. 12, 2019, which are incorporated herein by reference in their entirety.

### BACKGROUND

### 1. Field

Various embodiments of the present invention relate generally to a semiconductor device and, more particularly, to a memory device.

### 2. Description of the Related Art

Recently, the size of memory cells continues to be decreased in order to increase the net die of a memory device.

As the size of the memory cells is miniaturized, a parasitic capacitance has to be decreased while capacitance is increased. However, it is difficult to increase the net die due to structural limitations of the memory cells.

### SUMMARY

Embodiments of the present invention are directed to highly integrated vertical memory cell arrays, and a memory device including the highly integrated vertical memory cell arrays.

In accordance with an embodiment of the present invention, a memory device includes: a first memory cell mat that includes first multi-layer level sub word lines positioned over a substrate; a second memory cell mat that is laterally spaced apart from the first memory cell mat and includes second multi-layer level sub word lines; a first sub word line driver circuit that is positioned underneath the first memory cell mat; and a second sub word line driver circuit that is positioned underneath the second memory cell mat, wherein the first sub word line driver circuit is positioned underneath ends of the first multi-layer level sub word lines, and the second sub word line driver circuit is positioned underneath ends of the second multi-layer level sub word lines.

In accordance with another embodiment of the present invention, a memory device includes: a memory cell mat that includes multi-layer level sub word lines which are stacked in a direction perpendicular to an upper surface of a substrate; a sub word line driver circuit that is positioned underneath the memory cell mat and includes a plurality of sub word line drivers which respectively drive the multi-layer level sub word lines; a first level interconnection that electrically connects the multi-layer level sub word lines and the sub word line drivers to each other; and a second level interconnection that receives activation signals of the sub word line drivers and is positioned at a higher level than the first level interconnection.

In accordance with another embodiment of the present invention, a memory device includes: a sub word line driver circuit that includes sub word line drivers positioned over a substrate; a bit line and a plate line each of which is vertically oriented over the sub word line drivers; multi-layer level sub word lines that are positioned between the bit line and the plate line and arranged in a direction perpendicular to the substrate; and an interconnection that electrically connects the multi-layer level sub word lines to the sub word line drivers, wherein the sub word line drivers are positioned underneath ends of the multi-layer level sub word lines.

In accordance with another embodiment of the present invention, a memory device includes: first and second cell mats, each cell mat comprising a plurality of sub word line stacks, each sub word line stack including at least two vertically stacked sub word lines forming a step structure on two opposite ends of the sub word line stack, a sub word line driver circuit positioned underneath each of the first and second cell mats; and interconnections electrically coupling respective ends of each sub word line of each sub word line stack to the sub word line driver circuit.

### BRIEF DESCRIPTION OF THE DRAWINGS

FIG. 1 is an equivalent circuit diagram illustrating a memory device according to an embodiment of the present invention.

FIG. 2 is a perspective view illustrating a mirror-like structure sharing a plate line of FIG. 1.

FIG. 3 is an equivalent circuit diagram illustrating the mirror-like structure shown in FIG. 2.

FIG. 4 is a perspective view illustrating a mirror-like structure sharing a bit line shown in FIG. 1.

FIG. 5 is a cross-sectional view illustrating the memory device shown in FIG. 1.

FIG. 6 is a plan view illustrating the memory device shown in FIG. 1.

FIG. 7 is a perspective view showing details of a memory cell.

FIG. 8 is a cross-sectional view taken in a direction A1-A1′ of FIG. 7.

FIG. 9 is a plan view taken in a line A2-A2′ of FIG. 7.

FIG. 10 is a detailed perspective view of a capacitor.

FIGS. 11A to 11C are views illustrating a first node of a capacitor having a three-dimensional structure in accordance with another embodiment of the present invention.

FIGS. 12A and 12B are views illustrating a memory device in accordance with another embodiment of the present invention.

FIG. 13 is a perspective view illustrating a schematic structure of a memory device in accordance with another embodiment of the present invention.

FIG. 14A is a view illustrating a portion 300 of FIG. 13.

FIG. 14B is a cross-sectional view taken in a line A-A′ of FIG. 14A.

FIGS. 15 and 16 illustrate a connection relationship between one memory cell mat and a peripheral circuit portion.

FIG. 17 is an equivalent circuit diagram illustrating a sub word line driver circuit SWD of FIG. 16.

FIG. 18 is a layout illustrating the sub word line driver circuit SWD of FIG. 17.

FIG. 19 is a view illustrating interconnections coupled to the contacts of FIG. 18.

FIG. 20A is a perspective view illustrating a connection relationship between a first group sub word line and a first group sub word line driver circuit.

FIG. 20B is a perspective view illustrating a connection relationship between a second group sub word line and a second group sub word line driver circuit.

FIGS. 21 to 24E are views illustrating a memory device in accordance with other embodiments of the present invention.

FIG. 25 is a schematic plan view illustrating a semiconductor device according to an embodiment of the present invention.

FIG. 26A is a schematic cross-sectional view of the semiconductor device taken along line A-A′ of FIG. 25.

FIG. 26B is a schematic view illustrating a sub-word line driver circuit of FIG. 26A.

FIG. 27 is a schematic cross-sectional view of the semiconductor device taken along line B-B′ of FIG. 25.

FIG. 28 is a schematic view illustrating a semiconductor device according to an embodiment of the present invention.

FIGS. 29 to 31 are views illustrating an example of a method of fabricating the semiconductor device shown in FIG. 28.

FIG. 32 is a schematic view illustrating a semiconductor device according to an embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and, in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also to a case where a third layer exists between the first layer and the second layer or the substrate.

According to the following embodiments of the present invention, memory cell density may be increased and parasitic capacitance may be reduced by vertically stacking memory cells.

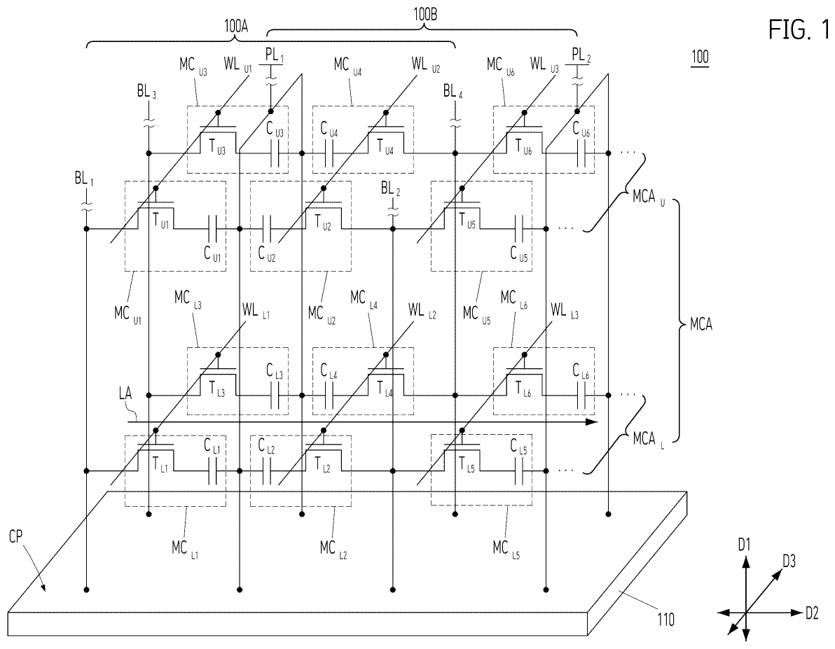

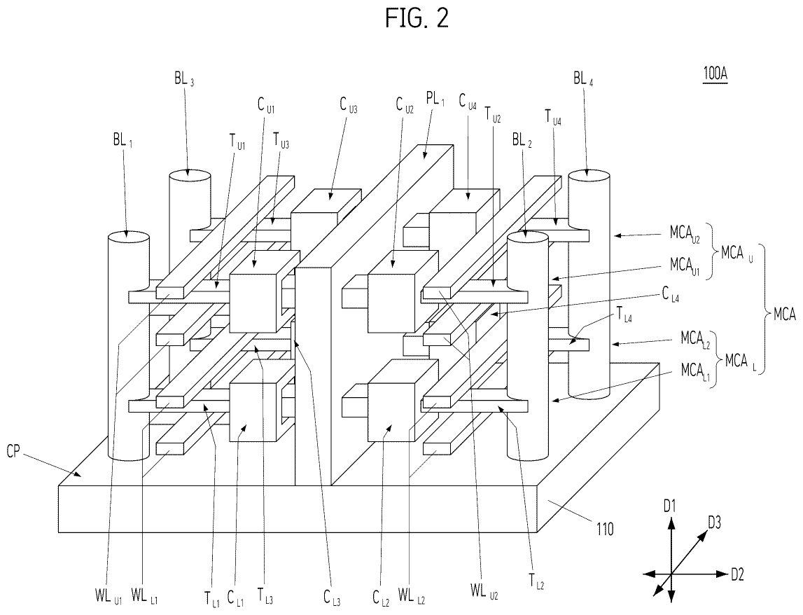

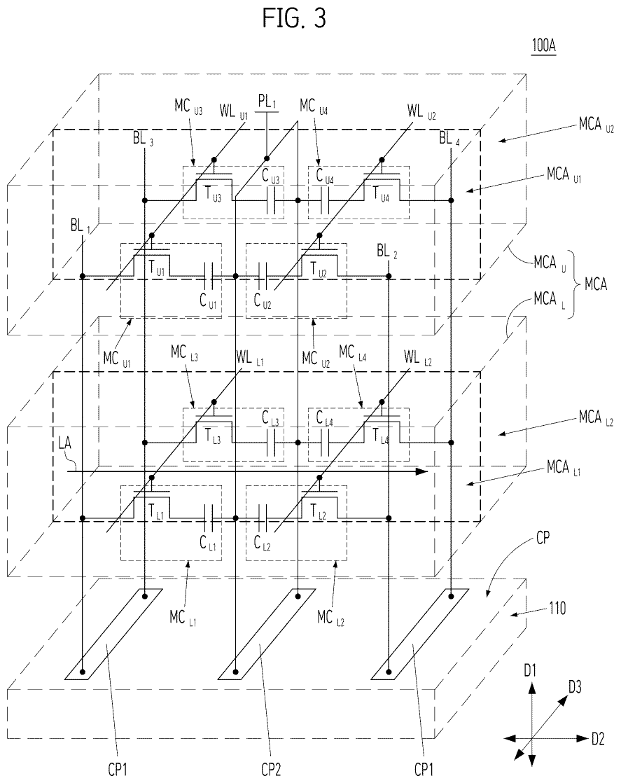

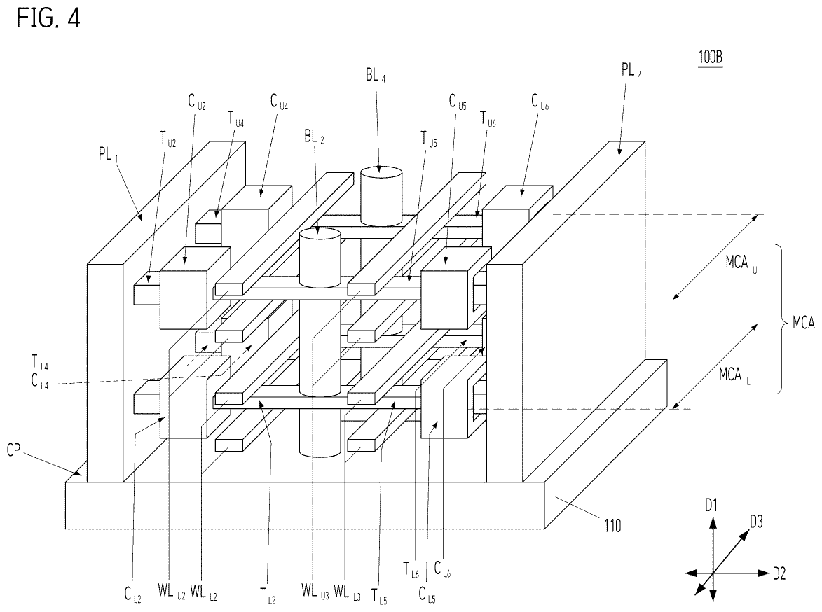

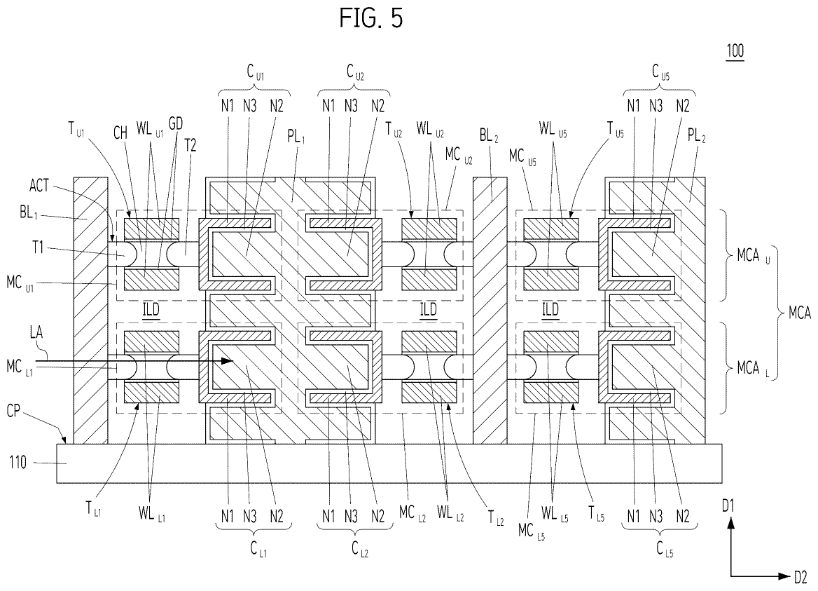

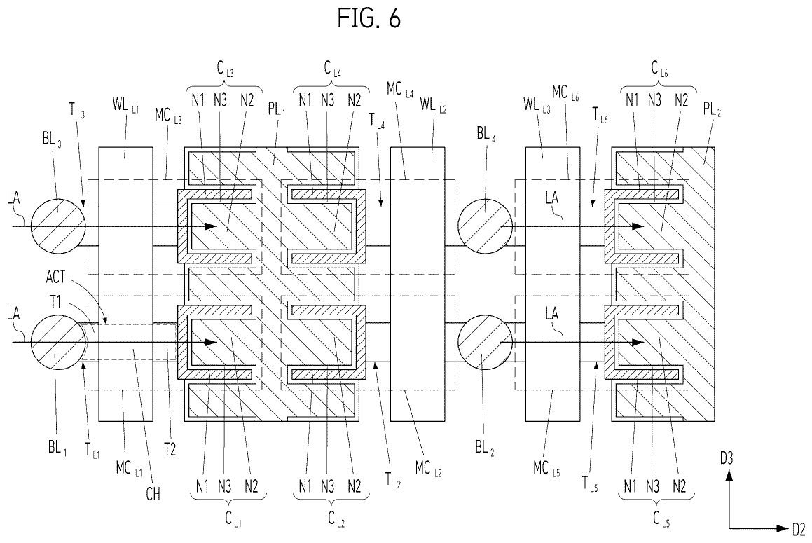

FIG. 1 is an equivalent circuit diagram illustrating a memory device according to an embodiment of the present invention. FIG. 2 is a perspective view illustrating a mirror-like structure 100A sharing a plate line of FIG. 1. FIG. 3 is an equivalent circuit diagram illustrating the mirror-like structure shown in FIG. 2. FIG. 4 is a perspective view illustrating a mirror-like structure 100B sharing a bit line shown in FIG. 1. FIG. 5 is a cross-sectional view illustrating the memory device shown in FIG. 1. FIG. 6 is a plan view illustrating the memory device shown in FIG. 1.

The memory device 100 may include a peripheral structure 110 and a memory cell array stack MCA. The memory cell array stack MCA may be positioned above the peripheral structure 110. The memory cell array stack MCA may include a plurality of memory cell arrays MCA_{L} and MCA_{U}. The positioning of the memory cell array stack MCA relatively to the peripheral structure 110 may vary according to various implementations of the present invention. For example, according to another embodiment of the present invention, the memory cell array stack MCA may be positioned below the peripheral structure 110.

The memory cell array stack MCA may include at least two memory cell arrays MCA_{L} and MCA_{U} stacked over the peripheral structure 110. The at least two memory cell arrays MCA_{L} and MCA_{U} may be vertically stacked over the peripheral structure 110. Generally, an n number of memory cell arrays may be stacked in the memory cell array stack MCA, where n is an integer equal to or greater than 2. According to an embodiment, the at least two memory cell arrays MCA_{L} and MCA_{U} may form one pair of memory cell arrays and the memory cell array stack MCA may include a plurality of pairs of memory cell arrays stacked over the peripheral structure 110. The plurality of pairs of memory cell arrays may be stacked vertically over the peripheral structure 110. In another embodiment, a plurality of pairs of memory cell arrays may be laterally arranged over the peripheral structure 110, each pair being identical to the pair of the at least two memory cell arrays MCA_{L} and MCA_{U}.

The peripheral structure 110 may include a material suitable for semiconductor processing including, for example, a semiconductor material. For example, the peripheral structure 110 may include a semiconductor substrate made of a semiconductor material, such as a silicon substrate, a monocrystalline silicon substrate, a polysilicon substrate, an amorphous silicon substrate, a silicon germanium substrate, a monocrystalline silicon germanium substrate, a polycrystalline silicon germanium substrate, a carbon-doped silicon substrate, or a combination thereof. The peripheral structure 110 may include a single-layer semiconductor substrate. The peripheral structure 110 may include a multi-layer semiconductor substrate. The peripheral structure 110 may include other semiconductor materials such as germanium. The peripheral structure 110 may include a III/V-group semiconductor substrate, for example, a compound semiconductor substrate such as GaAs. The peripheral structure 110 may include an SOI (Silicon-On-Insulator) substrate. The peripheral structure 110 may have a stacked structure of a semiconductor substrate and a dielectric material.

The surface of the peripheral structure 110 may include a plane CP. The memory cell array stack MCA may be positioned vertically over the plane CP of the peripheral structure 110. The memory cell array stack MCA may be formed in a first direction D1 perpendicular to the surface, i.e., the plane CP, of the peripheral structure 110. The first direction D1 may be a direction perpendicular to the plane CP, and the second direction D2 and the third direction D3 may be directions parallel to the plane CP. The second direction D2 and the third direction D3 may intersect with each other, and the first direction D1 may intersect with the second direction D2 and the third direction D3. The two memory cell arrays MCA_{L} and MCA_{U} may be grouped as one pair and a plurality of the pairs may be vertically stacked over the peripheral structure 110 in the first direction D1.

The plane CP of the peripheral structure 110 may include a first plane CP1 and a second plane CP2. The first plane CP1 and the second plane CP2 may be spaced apart from each other in a second direction D2 which is perpendicular to the first direction D1. The first plane CP1 and the second plane CP2 may be surfaces of the same material. The first plane CP1 and the second plane CP2 may be surfaces of different materials. The first plane CP1 and the second plane CP2 may be electrically insulated. The plane CP may be provided by a dielectric material. The top surface of the peripheral structure 110 may provide the plane CP. The top surface of the peripheral structure 110 may be of a dielectric material or a conductive material. The first plane CP1 and the second plane CP2 may be of a dielectric material or a conductive material. The first plane CP1 may be of a conductive material and the second plane CP2 may be of a dielectric material.

The two memory cell arrays MCA_{L} and MCA_{U} may be arranged above the plane CP of the peripheral structure 110. For the sake of convenience in description, the two memory cell arrays MCA_{L} and MCA_{U} may be respectively called a lower memory cell array MCA_{L} and an upper memory cell array MCA_{U}. A plurality of pairs each of which includes the two memory cell arrays MCA_{L} and MCA_{U} may be laterally arranged in a third direction D3 over the peripheral structure 110. For example, referring to FIGS. 2 and 3, the lower memory cell arrays MCA_{L1} and MCA_{L2} may be laterally arranged along the third direction D3, and the upper memory cell arrays MCA_{U1} and MCA_{U2} may be laterally arranged along the third direction D3.

The memory cell array stack MCA may include a plurality of word lines WL_{L1}, WL_{L2}, WL_{L3}, WL_{U1}, WL_{U2}, and WL_{U3}, a plurality of bit lines BL₁, BL₂, BL₃ and BL₄, a plurality of memory cells MC_{L1}, MC_{L2} and MC_{L3}, MC_{L4}, MC_{L5}, MC_{L6}, MC_{U1}, MC_{U2}, MC_{U3}, MC_{U4}, MC_{U5} and MC_{U6}, and a plurality of plate lines PL₁ and PL₂. The number of word lines, the number of bit lines, the number of memory cells, and the number of plate lines are not limited and may vary according to various implementations of the present invention.

The lower memory cell array MCA_{L} may include a plurality of word lines WL_{L1}, WL_{L2} and WL_{L3}, a plurality of bit lines BL₁, BL₂, BL₃ and BL₄, a plurality of memory cells MC_{L1}, MC_{L2}, MC_{L3}, MC_{L4}, MC_{L5} and MC_{L6}, and a plurality of plate lines PL₁ and PL₂. The upper memory cell array MCA_{U} may include a plurality of word lines WL_{U1}, WL_{U2} and WL_{U3}, a plurality of bit lines BL₁, BL₂, BL₃ and BL₄, a plurality of memory cells MC_{U1}, MC_{U2}, MC_{U3}, MC_{U4}, MC_{U5} and MC_{U6}, and a plurality of plate lines PL₁ and PL₂.

The bit lines BL₁, BL₂, BL₃ and BL₄ may extend along the first vertical direction D1 from the plane CP of the peripheral structure 110. The bit lines BL₁, BL₂, BL₃ and BL₄ may each be in direct contact with the plane CP of the peripheral structure 110. The bit lines BL₁, BL₂, BL₃ and BL₄ may be vertically oriented from a plane CP. The bit lines BL₁, BL₂, BL₃ and BL₄ may be referred to as vertically oriented bit lines VBL. The bit lines BL₁, BL₂, BL₃ and BL₄ may be parallel to each other while spaced apart from each other. The bit lines BL₁, BL₂, BL₃ and BL₄ may be independently arranged laterally while spaced apart from each other in the second direction D2 and the third direction D3. The bit lines BL₁ and BL₂ may be arranged independently along the second direction D2. The bit lines BL₁ and BL₃ may be independently arranged along the third direction D3. The bit lines BL₂ and BL₄ may be independently arranged along the third direction D3.

Memory cell MC_{L1} may be coupled to bit line BL₁. Memory cell MC_{U1} may be coupled to bit line BL₁. Memory cells MC_{L1} and MC_{U1} may be arranged vertically along the first direction D1 and may be coupled to bit line BL₁. The lower memory cell array MCA_{L} and the upper memory cell array MCA_{U} may share bit line BL₁. Memory cells MC_{L1} and MC_{U1} may be stacked vertically from the plane CP between the bit line BL₁ and the plate line PL₁. Bit line BL₃ may be positioned laterally away from the bit line BL₁ along the third direction D3. The bit line BL₃ may be vertically oriented from the plane CP. Memory cells MC_{L3} and MC_{U3} may be stacked vertically from the plane CP between the bit line BL₃ and the plate line PL₁. The memory cells MC_{L1} and MC_{U1} may each be commonly coupled with the plate line PL₁ and the bit line BL₁. The memory cells MC_{L3} and MC_{U3} may each be commonly coupled with the plate line PL₁ and the bit line BL₃.

Referring now to the bit line BL₂, memory cell MC_{L2} may be coupled to the bit line BL₂. Memory cell MC_{U2} may be coupled to the bit line BL₂. Memory cells MC_{L2} and MC_{U2} may be arranged vertically in the first direction D1 and may be coupled to bit line BL₂. The lower memory cell array MCA_{L} and the upper memory cell array MCA_{U} may share bit line BL₂. Bit line BL₄ may be positioned laterally away from the bit line BL₂ along the third direction D3. The bit line BL₄ may be vertically oriented from the plane CP. Memory cells MC_{L4} and MC_{U4} may be stacked vertically from the plane CP between the bit line BL₄ and the plate line PL₁. Memory cells MC_{L2} and MC_{U2} may be stacked vertically from the plane CP between the bit line BL₂ and the plate line PL₁. The memory cells MC_{L2} and MC_{U2} may each be commonly coupled with plate line PL₁ and the bit line BL₂. The memory cells MC_{L4} and MC_{U4} may each be commonly coupled with plate line PL₁ and the bit line BL₄.

Memory cell MC_{L3} may be coupled to the bit line BL₃. Memory cell MC_{U3} may be coupled to the bit line BL₃. Memory cells MC_{L3} and MC_{U3} arranged vertically in the first direction D1 may be coupled to the bit line BL₃. The lower memory cell array MCA_{L} and the upper memory cell array MCA_{U} may share the bit line BL₃.

Memory cell MC_{L4} may be coupled to bit line BL₄. Memory cell MC_{U4} may be coupled to bit line BL₄. Memory cells MC_{L4} and MC_{U4} arranged vertically in the first direction D1 may be coupled to the bit line BL₄. The lower memory cell array MCA_{L} and the upper memory cell array MCA_{U} may share the bit line BL₄.

As described above, the lower memory cell array MCA_{L} may include the bit lines BL₁, BL₂, BL₃ and BL₄. The upper memory cell array MCA_{U} may include the bit lines BL₁, BL₂, BL₃ and BL₄. The lower memory cell array MCA_{L} and the upper memory cell array MCA_{U} may each be commonly coupled with each of the bit lines BL₁, BL₂, BL₃ and BL₄.

The word lines WL_{L1}, WL_{L2}, WL_{U1}, WL_{U2}, WL_{L3} and WL_{U3} may be parallel to the surface of the peripheral structure 110 and may each extend in the third direction D3 which intersects with the first direction D1. The word lines WL_{L1}, WL_{L2}, WL_{U1}, WL_{U2}, WL_{L3} and WL_{U3} may be referred to as lateral word lines. The word lines WL_{L1}, WL_{L2}, WL_{U1}, WL_{U2}, WL_{L3} and WL_{U3} may be arranged in a direction intersecting with the bit lines BL₁, BL₂, BL₃ and BL₄. The word lines WL_{L1}, WL_{L2} and WL_{L3} may be positioned at a first level in the first direction D1. The word lines WL_{L1}, WL_{L2} and WL_{L3} may be positioned in the lower memory cell array MCA_{L}. The word lines WL_{L1}, WL_{L2} and WL_{L3} may be arranged at a regular interval along the second direction D2 and may each extend in the third direction D3. The word lines WL_{U1}, WL_{U2} and WL_{U3} may be positioned at a second level in the first direction D1. The word lines WL_{U1}, WL_{U2} and WL_{U3} may be positioned in the upper memory cell array MCA_{U}. The word lines WL_{U1}, WL_{U2} and WL_{U3} may be arranged at a regular interval along the second direction D2 and may each extend in the third direction D3. The second level may be further away from the peripheral structure 110 than the first level.

Referring now to the word line WL_{L1}, memory cell MC_{L1} may be coupled to the word line WL_{L1}. Memory cell MC_{L3} may be coupled to the word line WL_{L1}. Memory cells MC_{L1} and MC_{L3} may be laterally arranged while spaced apart from each other along the third direction D3 and may be coupled to the word line WL_{L1}. It is noted that reference to a word line being connected with a memory cell means that the gate of the memory cell is coupled with the word line.

Memory cell MC_{L2} may be coupled to the word line WL_{L2}. Memory cell MC_{L4} may be coupled to the word line WL_{L2}. Memory cells MC_{L2} and MC_{L4} may be laterally arranged while spaced apart from each other along the third direction D3 and may be coupled to the word line WL_{L2}.

Memory cell MC_{L5} may be coupled to the word line WL_{L3}. Memory cell MC_{L6} may be coupled to the word line WL_{L3}. Memory cells MC_{L5} and MC_{L6} may be laterally arranged while spaced apart from each other along the third direction D3 and may be coupled to the word line WL_{L3}.

Memory cell MC_{U1} may be coupled to the word line WL_{U1}. Memory cell MC_{U3} may be coupled to the word line WL_{U1}. Memory cells MC_{U1} and MC_{U3} may be laterally arranged while spaced apart from each other along the third direction D3 and may be coupled to the word line WL_{U1}.

Memory cell MC_{U2} may be coupled to the word line WL_{U2}. Memory cell MC_{U4} may be coupled to the word line WL_{U2}. Memory cells MC_{U2} and MC_{U4} may be laterally arranged while spaced apart from each other along the third direction D3 and may be coupled to the word line WL_{U2}.

Memory cell MC_{U5} may be coupled to the word line WL_{U3}. Memory cell MC_{U6} may be coupled to the word line WL_{U3}. Memory cells MC_{U5} and MC_{U6} may be laterally arranged while spaced apart from each other along the third direction D3 and may be coupled to the word line WL_{U3}.

As described above, the lower memory cell array MCA_{L} may include the word lines WL_{L1}, WL_{L2} and WL_{L3} that are parallel to each other while spaced apart from each other in the second direction D2, and the upper memory cell array MCA_{U} may include the word lines WL_{U1}, WL_{U2} and WL_{U3} that are parallel to each other while spaced apart from each other in the second direction D2.

Referring to FIG. 3, in an embodiment second plane CP2 may be disposed between left and right first planes CP1. The word line WL_{L1} of the lower memory cell array MCA_{L} and the word line WL_{U1} of the upper memory cell array MCA_{U} may be spaced apart from each other and arranged vertically from the left first plane CP1 in the first direction D1. The word line WL_{L2} of the lower memory cell array MCA_{L} and the word line WL_{U2} of the upper memory cell array MCA_{U} may be spaced apart from each other and arranged vertically from the second plane CP2 in the first direction D1. The word line WL_{L3} of the lower memory cell array MCA_{L} and the word line WL_{U3} of the upper memory cell array MCA_{U} may be spaced apart from each other and arranged vertically from the right first plane CP1 in the first direction D1.

The lower memory cell array MCA_{L} and the upper memory cell array MCA_{U} may each share plate line PL1 and PL2. (See FIG. 1) The plate lines PL1 and PL2 may each be oriented vertically from the plane CP of the peripheral structure 110 in the first direction D1. The plate lines PL1 and PL2 may be in direct contact with the plane CP of the peripheral structure 110 as illustrated in FIG. 1. However, according to a variation of the described embodiment, the plate lines PL1 and PL2 may not contact the plane CP of the peripheral structure 110. The plate lines PL1 and PL2 may intersect with the word lines WL_{L1}, WL_{L2}, WL_{L3}, WL_{U1}, WL_{U2} and WL_{U3} and may be parallel to the bit lines BL₁, BL₂, BL₃ and BL₄. The plate lines PL₁ and PL₂ may be set to a fixed potential (for example, a ground potential). According to the embodiment of the present invention, the plate lines PL1 and PL2 may be oriented in the first direction D1 vertically from the plane CP of the peripheral structure 110, and may be elongated in the direction D3 intersecting with the first direction D1. The plate lines PL1 and PL2 may be vertically oriented from the plane CP. The plate lines PL1 and PL2 may be referred to as vertical plate lines VPL. The plate lines PL1 and PL2 may be linear-shaped pillars extending laterally along the third direction D3 while vertically oriented in the first direction D1.

The bit lines BL₁, BL₂, BL₃ and BL₄ and the plate lines PL₁ and PL₂ may be spaced apart from each other over the plane CP. More specifically, the plate line PL₁ may be positioned between the bit lines BL₁ and BL₂ along the second direction D2. Referring to FIG. 3, the bit lines BL₁, BL₂, BL₃ and BL₄ may be coupled to the first plane CP1, and the plate lines PL₁ and PL₂ may be coupled to the second plane CP2. More specifically, bit lines BL₁, and BL₃ may be coupled to the left first plane CP1, the bit lines BL₂, and BL₄ may be coupled to the right first plane CP1, the plate line PL1 may be coupled to the second plane CP2 which is shown disposed between the left and right first planes CP1, and the plate line PL2 may be coupled to another second plane CP2 not shown in FIG. 3. The bit lines BL₁, BL₂, BL₃ and BL₄ and the plate lines PL₁ and PL₂ may be electrically insulated.

Each of the memory cells MC_{L1}, MC_{L3}, MC_{U1}, and MC_{U3} may be positioned between a plane defined by the bit lines BL₁ and BL₃ and a plane defined by the plate line PL₁. Each of the memory cells MC_{L2}, MC_{L4}, MC_{U2}, and MC_{U4} may be positioned between a plane defined by the bit lines BL₂ and BL₄ and a plane defined by the plate line PL₁. The memory cells MC_{L1}, MC_{L2}, and MC_{L5}, may be positioned in a lateral arrangement (LA) in the second direction D2. The memory cells MC_{U1}, MC_{U2}, and MC_{U5} may be positioned in a lateral arrangement (LA) in the second direction D2. The memory cells MC_{L3}, MC_{L4}, and MC_{L6}, may be positioned in a lateral arrangement (LA) in the second direction D2 and the memory cells MC_{U3}, MC_{U4}, and MC_{U6}, may be positioned in a lateral arrangement (LA) in the second direction D2. The memory cells MC_{L1}, MC_{L2}, MC_{L3}, MC_{L4}, MC_{L5}, MC_{L6}, MC_{U1}, MC_{U2}, MC_{U3}, MC_{U4}, MC_{U5}, and MC_{U6} may be positioned above the peripheral structure 110 which is spaced apart from the plane CP in four levels along the first direction D1, with each level having two rows spaced apart along the third direction D3, each row extending in the second direction D2.

Memory cell MC_{L1} may be coupled to the plate line PL₁. Memory cells MC_{L1} and MC_{U1} that are arranged vertically in the first direction D1 may be coupled to the plate line PL₁. Memory cells MC_{L1} and MC_{L2} may be laterally arranged while spaced apart from each other in the second direction D2 and may be coupled to the plate line PL₁. Memory cells MC_{L1} and MC_{L3} may be laterally arranged while spaced apart from each other along the third direction D3 and may be coupled to the plate line PL₁.

The memory cells MC_{L1}, MC_{L2}, MC_{L3}, MC_{L4}, MC_{U1}, MC_{U2}, MC_{U3} and MC_{U4} may include transistors T_{L1}, T_{L2}, T_{L3}, T_{L4}, T_{U1}, T_{U2}, T_{U3} and T_{U4} and capacitors C_{L1}, C_{L2}, C_{L3}, C_{L4}, C_{U1}, C_{U2}, C_{U3} and C_{U4}, respectively. The transistors T_{L1}, T_{L3}, T_{U1}, and T_{U3} and their respective capacitors C_{L1}, C_{L3}, C_{U1}, and C_{U3} may be positioned between the plane defined by the bit lines BL₁, and BL₃ and the plane of the plate line PL₁. The transistors T_{L2}, T_{L4}, T_{U2}, and T_{U4} and their respective capacitors C_{L2}, C_{L4}, C_{U2}, and C_{U4} may be positioned between the plane defined by the bit lines BL₂, and BL₄ and the plane of plate line PL₁ in the second direction D2. Each of the transistors T_{L1}, T_{L2}, T_{L3}, T_{L4}, T_{U1}, T_{U2}, T_{U3} and T_{U4} may be positioned in a lateral arrangement (LA) extending in the second direction D2 with its respective capacitor among the capacitors C_{L1}, C_{L2}, C_{L3}, C_{L4}, C_{U1}, C_{U2}, C_{U3} and C_{U4}. Each of the capacitors C_{L1}, C_{L2}, C_{L3}, C_{L4}, C_{U1}, C_{U2}, C_{U3} and C_{U4} may be positioned between its respective transistor among the transistors T_{L1}, T_{L2}, T_{L3}, T_{L4}, T_{U1}, T_{U2}, T_{U3} and T_{U4} and the plate line PL₁.

Referring to FIGS. 1, 2 and 3, a mirror-like structure 100A sharing a plate line is described.

The memory cell MC_{L1} may include the transistor T_{L1} and the capacitor C_{L1}. One end of the transistor T_{L1} may be coupled to the bit line BL₁ and the other end of the transistor T_{L1} may be coupled to one end of the capacitor C_{L1}. The other end of the capacitor C_{L1} may be coupled to the plate line PL₁. The memory cell MC_{L2} may include the transistor T_{L2} and the capacitor C_{L2}. One end of the transistor T_{L2} may be coupled to the bit line BL₂ and the other end of the transistor T_{L2} may be coupled to one end of the capacitor C_{L2}. The other end of the capacitor C_{L2} may be coupled to the plate line PL₁. As described above, the memory cells MC_{L1} and MC_{L2} may be symmetrically disposed with reference to the plate line PL₁.

That is, the memory cells MC_{L1} and MC_{L2} may be arranged in a mirror-like structure sharing the plate line PL₁ while being coupled to different bit lines BL₁ and BL₂. The memory cells MC_{L1} and MC_{L2} may be laterally arranged in the second direction D2 which is parallel to the plane CP.

Likewise, the memory cells MC_{L3} and MC_{L4} may be arranged in a mirror-like structure sharing the plate line PL₁ while being coupled to different bit lines BL₃ and BL₄. The memory cells MC_{L3} and MC_{L4} may be laterally arranged in the second direction D2 which is parallel to the plane CP.

The memory cells MC_{U1} and MC_{U2} may be arranged in a mirror-like structure sharing the plate line PL₁ while being coupled to different bit lines BL₁ and BL₂. The memory cells MC_{U1} and MC_{U2} may be laterally arranged in the second direction D2 which is parallel to the plane CP.

The memory cells MC_{U3} and MC_{U4} may be arranged in a mirror-like structure sharing the plate line PL₁ while being coupled to different bit lines BL₃ and BL₄. The memory cells MC_{U3} and MC_{U4} may be laterally arranged in the second direction D2 which is parallel to the plane CP.

Referring to FIGS. 1 and 4, a mirror-like structure 100B sharing a bit line is described.

The memory cell MC_{L2} may include the transistor T_{L2} and the capacitor C_{L2}. One end of the transistor T_{L2} may be coupled to the bit line BL₂ and the other end of the transistor T_{L2} may be coupled to one end of the capacitor C_{L2}. The other end of the capacitor C_{L2} may be coupled to the plate line PL1. The memory cell MC_{L5} may include the transistor T_{L5} and the capacitor C_{L5}. One end of the transistor T_{L5} may be coupled to the bit line BL₂ and the other end of the transistor T_{L5} may be coupled to one end of the capacitor C_{L5}. The other end of the capacitor C_{L5} may be coupled to the plate line PL2. As described above, the memory cells MC_{L2} and MC_{L5} are symmetrically disposed with reference to the bit line BL₂.

That is, the memory cells MC_{L2} and MC_{L5} may be arranged in a mirror-like structure sharing the bit line BL₂ while being coupled to different plate lines PL₁ and PL₂. The memory cells MC_{L2} and MC_{L5} may be laterally arranged in the second direction D2 which is parallel to the plane CP.

The memory cells MC_{L4} and MC_{L6} may be arranged in a mirror-like structure sharing the bit line BL₄ while being coupled to different plate lines PL₁ and PL₂. The memory cells MC_{L4} and MC_{L6} may be laterally arranged in the second direction D2 which is parallel to the plane CP.

The memory cells MC_{U2} and MC_{U5} may be arranged in a mirror-like structure sharing the bit line BL₂ while being coupled to different plate lines PL₁ and PL₂. The memory cells MC_{U2} and MC_{U5} may be laterally arranged in the second direction D2 which is parallel to the plane CP.

The memory cells MC_{U4} and MC_{U6} may be arranged in a mirror-like structure sharing the bit line BL₄ while being coupled to different plate lines PL₁ and PL₂. The memory cells MC_{U4} and MC_{U6} may be laterally arranged in the second direction D2 which is parallel to the plane CP.

The memory device 100 shown in FIG. 1 may include both of the mirror-like structure 100A sharing a plate line and the mirror-like structure 100B sharing a bit line.

FIG. 5 is a cross-sectional view illustrating a portion of the memory device 100 of FIG. 1, illustrating memory cells coupled to the bit lines BL₁ and BL₂ and the plate lines PL₁ and PL₂.

Referring to FIGS. 1 to 5, the memory device 100 may include a memory cell array stack MCA which is positioned above the peripheral structure 110, and the memory cell array stack MCA may include a lower memory cell array MCA_{L} and an upper memory cell array MCA_{U} that are vertically stacked. The memory device 100 may include bit lines BL₁ and BL₂ and plate lines PL₁ and PL₂ that are spaced apart from each other and vertically oriented relatively to the peripheral structure 110.

The memory cells MC_{L1} and MC_{U1} including transistors T_{L1} and T_{U1} and capacitors C_{L1} and C_{U1}, respectively, may be formed between the bit line BL₁ and the plate line PL₁. Also, the memory cells MC_{L2} and MC_{U2} including transistors T_{L2} and T_{U2} and capacitors C_{L2} and C_{U2} respectively, may be formed between the bit line BL₂ and the plate line PL₁. The memory cells MC_{L5} and MC_{U5} including transistors T_{L5} and Tus and capacitors C_{L5} and C_{U5} respectively, may be formed between the bit line BL₂ and the plate line PL₂. The memory cells MC_{L1}, MC_{L2}, and MC_{L5} may be positioned at the same level in relation to the first direction D1 and in a lateral arrangement spaced apart from each other along the second direction D2. The memory cells MC_{U1}, MC_{U2}, and MC_{U5} may be positioned at the same level in relation to the first direction D1 and in a lateral arrangement spaced apart from each other along the second direction D2. The transistor and capacitor forming each memory cell may be arranged laterally to each other along the second direction D2.

Each of the transistors T_{L1}, T_{L2}, T_{L5}, T_{U1}, T_{U2} and Tus may include an active layer ACT which is laterally oriented with respect to the peripheral structure 110, and the active layer ACT may include a first source/drain region T1, a channel CH, and a second source/drain region T2. The first source/drain region T1, the channel CH, and the second source/drain region T2 may be positioned in a lateral arrangement along the second direction D2 which is parallel to the peripheral structure 110. The transistors T_{L1}, T_{L2}, T_{L5}, T_{U1}, T_{U2} and Tus may include word lines WL_{L1}, WL_{L2}, WL_{L5}, WL_{U1}, WL_{U2} and WL_{U5}, respectively, and the word lines WL_{L1}, WL_{L2}, WL_{L5}, WL_{U1}, WL_{U2} and WL_{U5} may be in a line shape extending so as to intersect with the active layer ACT. As illustrated in FIG. 5, the word lines WL_{L1}, WL_{L2}, WL_{L5}, WL_{U1}, WL_{U2} and WL_{U5} may be of a double word line structure in which the word lines are vertically stacked with the active layer ACT between them. Each of the word lines WL_{L1}, WL_{L2}, WL_{L5}, WL_{U1}, WL_{U2} and WL_{U5} may be composed of two conductive layers with the active layer ACT therebetween. A gate dielectric layer GD may be formed between each of the word lines WL_{L1}, WL_{L2}, WL_{L5}, WL_{U1}, WL_{U2} and WL_{U5} and the corresponding active layer ACT.

The capacitors C_{L1}, C_{L2}, C_{L5}, C_{U1}, C_{U2} and C_{U5} may each include a first node N1, a second node N2, and a dielectric material N3 between the first node N1 and the second node N2. The first node N1, the dielectric material N3, and the second node N2 may be positioned in a lateral arrangement which is parallel to the peripheral structure 110. According to the cross-sectional view of FIG. 5, each first node N1 may have a square bracket shape facing towards a respective plate line. Specifically, each first node N1 of the capacitors C_{L1}, C_{L2}, C_{U1}, and C_{U2} may have a square bracket shape (“[” or “]”) facing towards the plate line PL1 and each first node N1 of the capacitors C_{L5} and C_{U5} may have a square bracket shape facing towards the plate line PL2. Stated otherwise the first node N1 may have a cylinder shape with one end of the cylinder being open. The horizontal parts of the bracket shape extending in the second direction D2 of each of the first nodes N1 may be longer than the part extending in the first direction D1 as illustrated in FIG. 5. The dielectric material N3 may be formed conformally within the interior surface of each first node N1 to leave a central region within each first node N1 to be filled with the second node N2. The second node N2 may extend from the respective plate line PL₁ or PL₂ to fill the inside of the central region of the first node N1. The dielectric material N3 may be disposed between each pair of first and second nodes N1 and N2.

Dielectric materials ILD may be formed between the lower memory cells MC_{L1}, MC_{L2} and MC_{L5} and the upper memory cells MC_{U1}, MC_{U2} and MC_{U5} that are vertically stacked. Thus, in the memory cell array stack MCA, the dielectric materials ILD may be positioned between the lower memory cell array MCA_{L} and the upper memory cell array MCA_{U}. When a plurality of memory cell arrays are stacked, the lower memory cell arrays MCA_{L}, the dielectric materials ILD, and the upper memory cell arrays MCA_{U} may be alternately stacked vertically.

FIG. 6 is a plan view illustrating the lower memory cell array MCA_{L} of the memory cell array stack MCA.

Referring to FIGS. 1 to 6, the lower memory cell array MCA_{L} may include bit lines BL₁, BL₂, BL₃ and BL₄ and plate lines PL₁ and PL₂. The bit lines BL₁, BL₂, BL₃ and BL₄ and the plate lines PL₁ and PL₂ may be vertically oriented from the peripheral structure 110, individually. The bit lines BL₁, BL₂, BL₃ and BL₄ and the plate lines PL₁ and PL₂ may be spaced apart from each other.

A memory cell MC_{L1} including a transistor T_{L1} and a capacitor C_{L1} that are positioned in a lateral arrangement (LA) between the bit line BL₁ and the plate line PL₁ may be formed. A memory cell MC_{L3} including a transistor T_{L3} and a capacitor C_{L3} that are positioned in a lateral arrangement (LA) between the bit line BL₃ and the plate line PL₁ may be formed. A memory cell MC_{L2} including a transistor T_{L2} and a capacitor C_{L2} that are positioned in a lateral arrangement (LA) between the bit line BL₂ and the plate line PL₁ may be formed. A memory cell MC_{L4} including a transistor T_{L4} and a capacitor C_{L4} that are positioned in a lateral arrangement (LA) between the bit line BL₄ and the plate line PL₁ may be formed.

A memory cell MC_{L5} including a transistor TLs and a capacitor C_{L5} that are positioned in a lateral arrangement (LA) between the bit line BL₂ and the plate line PL₂ may be formed. A memory cell MC_{L6} including a transistor T_{L6} and a capacitor C_{L6} that are positioned in a lateral arrangement (LA) between the bit line BL₄ and the plate line PL₂ may be formed.

Each of the transistors T_{L1}, T_{L2}, T_{L3}, T_{L4}, TLS and T_{L6} may include an active layer ACT which is laterally oriented with respect to the peripheral structure 110, and the active layer ACT may include a first source/drain region T1, a channel CH, and a second source/drain region T2. The first source/drain region T1, the channel CH, and the second source/drain region T2 may be positioned in a lateral arrangement LA which is parallel to the peripheral structure 110. The transistors T_{L1}, T_{L2}, may include the word line WL_{L1}, the transistors T_{L3}, T_{L4}, may include the word line WL_{L2} and the transistors T_{L5} and T_{L6} may include the word line WL_{L3}. The word lines WL_{L1}, WL_{L2} and WL_{L3} may each have a shape of a line that extends in the third direction D3. The word lines WL_{L1}, WL_{L2} and WL_{L3} may each have a shape of a line that extends in the third direction D3 to overlap with the channel CH of the active layer ACT of respective transistors. Specifically, the word line WL_{L1}, may overlap with the channel CH of the active layer ACT of transistors T_{L1} and T_{L3}, the word lines WL_{L2}, may overlap with the channel CH of the active layer ACT of transistors T_{L2} and T_{L4}, and the word line WL_{L3}, may overlap with the channel CH of the active layer ACT of transistors T_{L5} and T_{L6}. The word lines WL_{L1}, WL_{L2} and WL_{L3} may have a double word line structure in which the word lines WL_{L1}, WL_{L2} and WL_{L3} are vertically stacked with the respective active layers ACT between them. The transistors T_{L1} and T_{L3} may be commonly coupled with word line WL_{L1}, the transistors T_{L2} and T_{L4} may be commonly coupled with word line WL_{L2}, and the transistors T_{L5} and T_{L6} may be commonly coupled with word line WL_{L3}.

The capacitors C_{L1}, C_{L2}, C_{L3}, C_{L4}, C_{L5} and C_{L6} may each include the first node N1, the second node N2, and the dielectric material N3 between the first node N1 and the second node N2. According to the view of FIG. 6, each first node N1 may have a square bracket shape facing towards a respective plate line. Specifically, each first node N1 of the capacitors C_{L1}, C_{L2}, C_{L3}, and C_{L4} may have a square bracket shape (“[” or “]”) facing towards the plate line PL₁ and each first node N1 of the capacitors CLs and C_{L6} may have a square bracket shape facing towards the plate line PL₂. The horizontal parts of the bracket shape extending in the second direction D2 of each of the first nodes N1 may be longer than the part extending in the third direction D3 as illustrated in FIG. 6. The dielectric material N3 may be formed conformally within the interior surface of each first node N1 to leave a central region within each first node N1 to be filled with the second node N2. The second node N2 may extend from the respective plate line PL₁ or PL₂ to fill the inside of the central region of the first node N1. The dielectric material N3 may be disposed between each pair of first and second nodes N1 and N2.

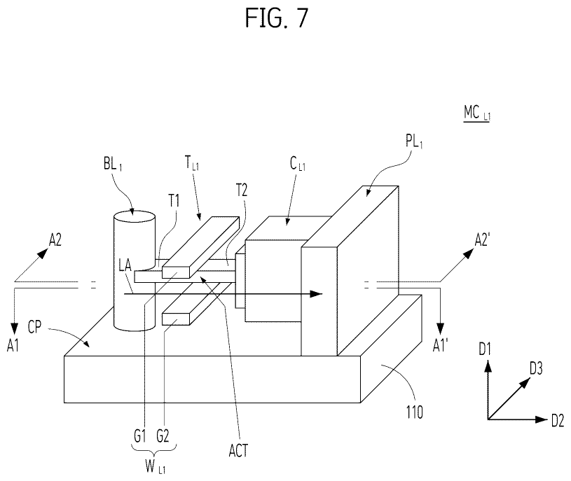

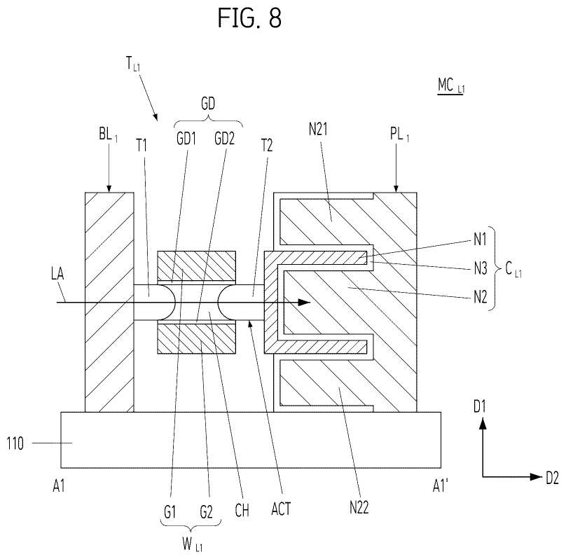

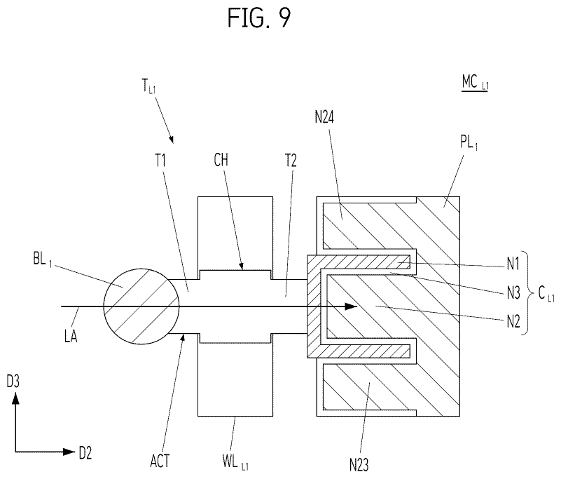

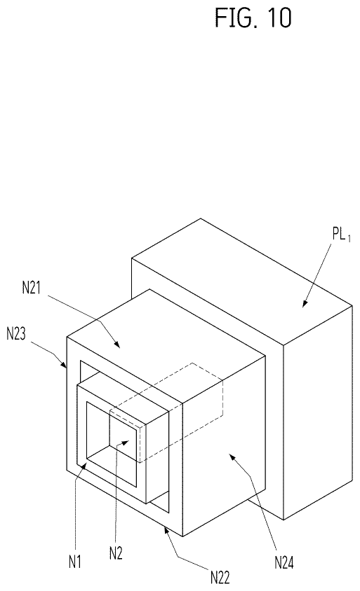

FIG. 7 is a perspective view showing details of a memory cell. FIG. 8 is a cross-sectional view taken in a line A1-A1′ of FIG. 7. FIG. 9 is a plan view taken in a line A2-A2′ of FIG. 7. FIG. 10 is a detailed perspective view of a capacitor. FIGS. 7 to 10 illustrate the memory cell MC_{L1}.

Referring to FIGS. 7 to 10, the memory cell MC_{L1} may be positioned in a lateral arrangement (LA) in the second direction D2 which is parallel to the plane CP of the peripheral structure 110 between the bit line BL₁ and the plate line PL₁.

The memory cell MC_{L1} may include a transistor T_{L1} and a capacitor C_{L1}. The transistor T_{L1} and the capacitor C_{L1} may be positioned in a lateral arrangement (LA) extending in the second direction D2 which is parallel to the plane CP of the peripheral structure 110.

The transistor T_{L1} may include an active layer ACT, a gate dielectric layer GD, and a word line WL_{L1}. The word line WL_{L1} may include an upper word line G1 and a lower word line G2. That is, the word line WL_{L1} may have the double word line structure in which the upper and lower word lines G1 and G2 are stacked with the active layer ACT therebetween.

The active layer ACT may include a first source/drain region T1 coupled to the bit line BL₁, a second source/drain region T2 coupled to the capacitor C_{L1}, and a channel CH positioned between the first source/drain region T1 and the second source/drain region T2. The active layer ACT may be laterally oriented in the second direction D2 between the bit line BL₁ and the capacitor C_{L1}. The active layer ACT may have the shape of an elongated flat plate. The first source/drain region T1, the channel CH, and the second source/drain region T2 may be positioned in a lateral arrangement LA which is oriented in the second direction D2 which is parallel to the plane CP. The first source/drain region T1, the second source/drain region T2, and the channel CH may be formed in the active layer ACT. The active layer ACT may be formed to include any suitable semiconductor material. For example, the active layer ACT may include doped polysilicon, undoped polysilicon, or amorphous silicon. The first source/drain region T1 and the second source/drain region T2 may be doped with an N-type impurity or a P-type impurity. The first source/drain region T1 and the second source/drain region T2 may be doped with an impurity of the same conductivity type. The first source/drain region T1 and the second source/drain region T2 may include at least one impurity selected from a group including arsenic (As), phosphorus (P), boron (B), indium (In), and combinations thereof. In some embodiments of the present invention, the channel CH may be doped with a conductive impurity. Referring to FIG. 9, the width of the channel CH along the third direction D3 may be greater than the width of the first and second source/drain regions T1 and T2.

The upper word line G1 and the lower word line G2 may form a single pair. The upper word line G1 and the lower word line G2 may be vertically stacked while spaced apart from each other in the first direction D1 with the channel CH interposed therebetween, and may be oriented along the third direction D3. The upper word line G1 and the lower word line G2 may be parallel to the plane CP, and extend along the third direction D3 which is perpendicular to the second direction D2. The upper word line G1 and the lower word line G2 may have a shape of lines extending along the third direction D3. The pair of the upper word line G1 and the lower word line G2 may form a vertically stacked double gate. The upper word line G1 and the lower word line G2 may include a silicon-based material, a metal-based material, or a combination thereof. The upper word line G1 and the lower word line G2 may include polysilicon, titanium nitride, tungsten, aluminum, copper, tungsten silicide, titanium silicide, nickel silicide, cobalt silicide or a combination thereof.

The upper word line G1 and the lower word line G2 may be set to the same potential, and one end of the upper word line G1 and one end of the lower word line G2 may be electrically connected to each other at an end of an array of units of mats or blocks of a plurality of memory cells. In an embodiment, the upper word line G1 and the lower word line G2 of the memory cells MC_{L1} may be connected to different nodes. The upper word line G1 may be connected to a node for applying a first voltage, and the lower word line G2 may be connected to another node applied with a second voltage. The first voltage and the second voltage are different from each other. For example, the upper word line G1 may be applied with a word line driving voltage, the lower word line G2 may be applied with a ground voltage. The upper word line G1 and the lower word line G2 may have the same width in the second direction D2 and the same length along the third direction D3. The upper word line G1 and the lower word line G2 may have the same thickness (dimension in the first direction D1). The upper word line G1, the lower word line G2, and the active layer ACT may have the same thickness or different thicknesses. Both-side edges of the upper word line G1 and both-side edges of the lower word line G2 may be aligned with each other. According to another embodiment of the present invention, both-side edges of the upper word line G1 and both-side edges of the lower word line G2 may not be aligned with each other. The upper word line G1 and the lower word line G2 may overlap with the channel CH of the active layer ACT in the first direction D1. The upper word line G1 and the lower word line G2 may partially cover the upper and lower portions of the active layer ACT. The upper word line G1 and the lower word line G2 may be formed of a material which is different from that of the active layer ACT. The upper word line G1 and the lower word line G2 may be paired. The word line resistance may be lowered because a pair of word lines including the upper word line G1 and the lower word line G2 is formed. In addition, since a pair of the upper word line G1 and the lower word line G2 are formed, interference between the memory cells that are vertically adjacent to each other may be prevented. For example, the lower word line G2 of the memory cell MC_{U1} may be provided between the upper word line G1 of the memory cell MC_{L1} and the upper word line G1 of the memory cell MC_{U1}. The lower word line G2 may be used to inhibit/prevent adjacent ones of the upper word lines G1 from being electrically coupled to each other.

The gate dielectric layer GD may be formed on the upper surface and the lower surface of the active layer ACT, individually. The gate dielectric layer GD may include a first dielectric portion GD1 and a second dielectric portion GD2. The first dielectric portion GD1 may be formed between the upper word line G1 and the channel CH, and the second dielectric portion GD2 may be formed between the lower word line G2 and the channel CH. The first dielectric portion GD1 may be discontinuous from the second dielectric portion GD2. The first dielectric portion GD1 and the second dielectric portion GD2 may have the same thickness and may be formed of the same material. The gate dielectric layer GD may include silicon oxide, silicon nitride, or a combination thereof. The gate dielectric layer GD may be formed by thermal oxidation of the active layer ACT. According to another embodiment of the present invention, the gate dielectric layer GD may include a high dielectric material, and the high dielectric material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). According to another embodiment of the present invention, the gate dielectric layer GD may include a stack of silicon oxide and a high dielectric material, the silicon oxide may be in direct contact with the channel CH, and the high dielectric material may be in direct contact with the upper word line G1 and the lower word line G2.

The capacitor C_{L1} may include a first node N1 coupled to the transistor T_{L1}, a second node N2 coupled to the plate line PL₁, and a dielectric material N3 disposed between the first node N1 and the second node N2. The dielectric material N3 may form a continuous layer between the first node N1 and the second node N2. The first node N1, the dielectric material N3, and the second node N2 may be positioned in a lateral arrangement which is parallel to the plane CP.

The first node N1 of the capacitor C_{L1} may have a three-dimensional structure. The first node N1 of the three-dimensional structure may be a lateral three-dimensional structure which is parallel to the plane CP. As an example of the three-dimensional structure, the first node N1 of the capacitor C_{L1} may have a cylindrical shape, a pillar shape, or a pylinder shape (i.e., a merged form of a pillar shape and a cylindrical shape). The first node N1 may include polysilicon, metal, noble metal, a metal nitride, a conductive metal oxide, a conductive noble metal oxide, a metal carbide, a metal silicide, or a combination thereof. For example, the first node N1 may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a stack of titanium nitride and tungsten (TiN/W), or a stack of tungsten nitride and tungsten (WN/W).

The second node N2 of the capacitor C_{L1} may have a branch shape extending in the second direction D2 which is parallel to the plane CP from the plate line PL₁. The dielectric material N3 may have a shape surrounding the second node N2 having a form of branch, and the first node N1 may have a shape surrounding the second node N2 with the dielectric material N3 interposed therebetween. For example, the first node N1 having a cylindrical shape may be electrically connected to the second source/drain region T2 of the transistor T_{L1}, and the second node N2 may be positioned in the inside of the cylindrical shape of the first node N1, and the second node N2 may be electrically connected to the plate line PL₁.

Referring to FIG. 10, the second node N2 of the capacitor C_{L1} may further include outer second nodes N21, N22, N23 and N24 coupled to the plate line PL₁. The outer second nodes N21, N22, N23 and N24 may be positioned outside the first node N1 with the dielectric material N3 interposed therebetween. The second node N2 may be abbreviated as an ‘inner second node’, and the inner second node N2 may be positioned inside the cylindrical shape of the first node N1.

The outer second nodes N21, N22, N23 and N24 may be positioned to surround the outer wall of the cylindrical shape of the first node N1. The outer second nodes N21, N22, N23 and N24 may be in continuum with each other.

The capacitor C_{L1} may include a metal-insulator-metal (MIM) capacitor. The first node N1 and the second nodes N2, N21, N22, N23 and N24 may include a metal-based material, and the dielectric material N3 may include silicon oxide, silicon nitride, or a combination thereof. The dielectric material N3 may include a high dielectric (high-k) material having a higher dielectric constant than that of silicon oxide (SiO₂) which has a dielectric constant of approximately 3.9. The dielectric material N3 may include a high dielectric material having a dielectric constant of approximately 4 or higher. The high dielectric material may have a dielectric constant of approximately 20 or more. The high dielectric material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). According to another embodiment of the present invention, the dielectric material N3 may be a composite layer including two or more layers of the aforementioned high-dielectric materials.

The first node N1 and the second nodes N2, N21, N22, N23 and N24 may include a metal, a noble metal, a metal nitride, a conductive metal oxide, a conductive noble metal oxide, a metal carbide, a metal silicide, or a combination thereof. For example, the first node N1 and the second nodes N2, N21, N22, N23 and N24 may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a stack of titanium nitride/tungsten (TiN/W), a stack of tungsten nitride/tungsten (WN/W). The first node N1 and the second nodes N2, N21 and N22 may include a combination of a metal-based material and a silicon-based material. For example, the second nodes N2, N21, N22, N23 and N24 may be a stack of titanium nitride/silicon germanium/tungsten nitride (TiN/SiGe/WN).

The dielectric material N3 may be formed of a zirconium-based oxide. The dielectric material N3 may have a stack structure including zirconium oxide (ZrO₂). The stack structure including zirconium oxide (ZrO₂) may include a ZA (ZrO₂/Al₂O₃) stack or a ZAZ (ZrO₂/Al₂O₃/ZrO₂) stack. The ZA stack may be a structure in which aluminum oxide (Al₂O₃) is stacked over zirconium oxide (ZrO₂), and zirconium oxide (ZrO₂) may contact the first node N1, while aluminum oxide (Al₂O₃) may contact the second node N2. The ZAZ stack may be a structure in which zirconium oxide (ZrO₂), aluminum oxide (Al₂O₃), and zirconium oxide (ZrO₂) are sequentially stacked. The ZA stack and the ZAZ stack may be referred to as a zirconium oxide-based layer. According to another embodiment of the present invention, the dielectric material N3 may be formed of a hafnium-based oxide. The dielectric material N3 may have a stack structure including hafnium oxide (HfO₂). The stack structure including hafnium oxide (HfO₂) may include an HA (HfO₂/Al₂O₃) stack or an HAH (HfO₂/Al₂O₃/HfO₂) stack. The HA stack may be a structure in which aluminum oxide (Al₂O₃) is stacked over hafnium oxide (HfO₂), and hafnium oxide (HfO₂) may contact the first node N1, and aluminum oxide (Al₂O₃) may contact the second node N2. The HAH stack may be a structure in which hafnium oxide (HfO₂), aluminum oxide (Al₂O₃), and hafnium oxide (HfO₂) are sequentially stacked. The HA stack and the HAH stack may be referred to as a hafnium oxide-based layer (HfO₂-based layer). In the ZA stack, the ZAZ stack, the HA stack, and the HAH stack, the aluminum oxide (Al₂O₃) may have a band gap energy which is larger than those of zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Thus, the dielectric material N3 may include a stack of a high dielectric material and a high-band gap energy material whose band gap energy is greater than the high dielectric material. The dielectric material N3 may include silicon oxide (SiO₂) as another high-band gap energy material other than aluminum oxide (Al₂O₃). The dielectric material N3 may include a high-band gap energy material so that the leakage current may be suppressed. The high-band gap energy material may be extremely thin. The high-band gap energy material may be thinner than the high dielectric material.

According to another embodiment of the present invention, the dielectric material N3 may have a laminated structure in which a high dielectric material and a high-band gap material are alternately stacked. For example, the dielectric material N3 may have ZAZA (ZrO₂/Al₂O₃/ZrO₂/Al₂O₃), ZAZAZ (ZrO₂/Al₂O₃/ZrO₂/Al₂O₃/ZrO₂), HAHA (HfO₂/Al₂O₃/HfO₂/Al₂O₃) or HAHAH (HfO₂/A1₂O₃/HfO₂/Al₂O₃/HfO₂). In the laminated structure, the aluminum oxide (Al₂O₃) may be extremely thin.

According to another embodiment of the present invention, the dielectric material N3 may include a stack structure, a laminated structure or an inter-mixing structure including zirconium oxide, hafnium oxide, and aluminum oxide.

According to another embodiment of the present invention, an interface controlling layer may be further formed to improve the leakage current between the first node N1 and the dielectric material N3. The interface controlling layer may include titanium oxide (TiO₂). The interface controlling layer may be formed between the second node N2 and the dielectric material N3.

The bit line BL₁ and the plate line PL₁ may include a silicon-based material, a metal-base material or a combination thereof. The bit line BL₁ may include polysilicon, titanium nitride, tungsten, or a combination thereof. For example, the bit line BL₁ may include polysilicon doped with an N-type impurity or titanium nitride (TiN). The bit line BL₁ may include a stack of titanium nitride and tungsten (TiN/W). An ohmic contact such as a metal silicide may be further formed between the bit line BL₁ and the first source/drain region T1 of the transistor T_{L1}. The plate line PL₁ may be formed of the same material as that of the second nodes N2, N21, N22, N23 and N24. The plate line PL₁ and the second nodes N2, N21, N22, N23 and N24 may be formed simultaneously.

The bit line BL₁ may have a form of a pillar vertically extending from the plane CP in the first direction D1. A cross-section of the bit line BL₁ taken in the second direction D2 may be circle-shaped or oval-shaped. The pillar-shaped bit line BL₁ may have a low resistance.

The plate line PL₁ may be a linear shape vertically extending from the plane CP in the first direction D1. The cross-sections of the plate line PL₁ in the first, second direction, and third directions D1, D2, and D3 may be rectangles of different areas. The plate line PL₁ may have a width (dimension in the second direction D2) that is smaller than its length (dimension in the third direction D3) and also smaller than its height (dimension in the first direction D1). More specifically, the width (dimension in the second direction D2) of the plate line PL₁ may be the same as the width (dimension in the second direction D2) of the word line W_{L1} as shown in FIG. 7. The height (dimension in the first direction D1) of the plate line PL₁ may be such that the top surface of the plate line PL₁ is positioned higher than a top surface of a first node N1 of a capacitor (e.g., C_{U2}) of a top memory cell (e.g., MC_{U2}) of the upper memory cell array MCA_{U}. The length (dimension in the third direction D3) of the plate line PL₁ may be such that the plate line may be coextensive in the third direction with the word lines.

According to the above description, the upper word line G1 and the lower word line G2 may be formed to be laterally spaced apart from the bit line BL₁ and the plate line PL₁. Accordingly, the parasitic capacitance between the word line WL_{L1} and the capacitor C_{L1} may be decreased, and the parasitic capacitance between the word line WL_{L1} and the bit line BL₁ may be reduced.

The method of forming the memory cell MC_{L1} of FIGS. 7 to 10 may include a process of forming the transistor T_{L1}, a process of forming the bit line BL₁, a process of forming the capacitor C_{L1}, and a process of forming the plate line PL₁.

A process of forming the transistor T_{L1} will now be described. An active layer ACT may be formed to be vertically (i.e., in the first direction D1) spaced apart from the plane CP of a top surface of the peripheral structure 110, and gate dielectric layers GD1 and GD2 may be formed on the upper and lower surfaces of the active layer ACT. Subsequently, the upper word line G1 and the lower word line G2 may be formed over the gate dielectric layers GD1 and GD2, respectively. Subsequently, the first source/drain region T1 and the second source/drain region T2 may be formed through ion implantation of an impurity into the active layer ACT.

The bit line BL₁ may be formed to be vertically oriented from the plane CP of the peripheral structure 110. The bit line BL₁ may be formed to be coupled to the first source/drain region T1.

The process of forming the capacitor C_{L1} will now be described. First, a first node N1 may be formed to be coupled to the second source/drain region T2. Subsequently, a dielectric material N3 may be formed over the first node N1. Subsequently, a second node N2 may be formed over the dielectric material N3. A plate line PL₁ may be formed while the second node N2 is formed. The plate line PL₁ may be vertically oriented from the plane CP of the peripheral structure 110.

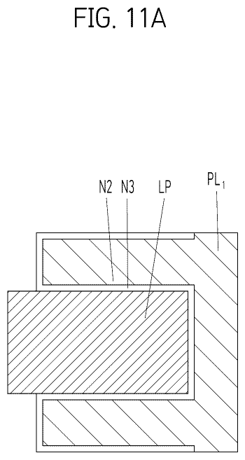

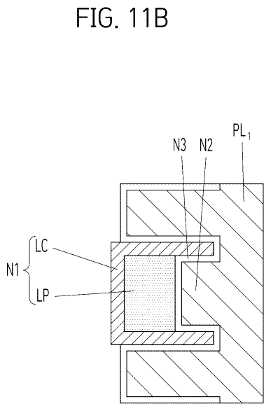

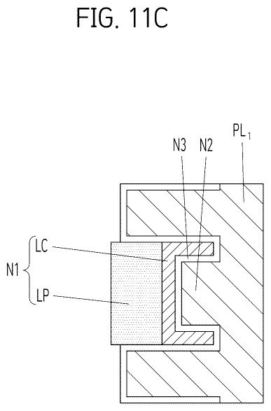

FIGS. 11A to 11C are views illustrating a first node of a capacitor having a three-dimensional structure in accordance with another embodiment of the present invention. FIG. 11A shows a pillar-shaped first node N1, and FIGS. 11B and 11C show a first node N1 having a form of a pylinder, i.e., a combination of a pillar and a cylinder structure.

Referring to FIG. 11A, the first node N1 may be a lateral pillar LP. A lateral pillar LP may include a metal-based material, a silicon-based material, or a combination thereof. For example, the lateral pillar LP may be formed of titanium nitride alone or may be formed of a stack of titanium nitride and polysilicon.

Referring to FIGS. 11B and 11C, the first node N1 having the form of a pylinder may include a lateral cylinder LC and a lateral pillar LP that are parallel to the plane CP. Referring to FIG. 11B, the lateral pillar LP may be positioned in the inside of the lateral cylinder LC. The lateral length of the lateral cylinder LC may be longer than the lateral length of the lateral pillar LP. For example, the inlet of the lateral cylinder LC may not be filled with the lateral pillar LP. Referring to FIG. 11C, the lateral cylinder LC may be formed in a lateral arrangement over the lateral pillar LP.

Referring to FIG. 11B, the lateral cylinder LC and the lateral pillar LP may be of the same material or different materials. The lateral cylinder LC and the lateral pillar LP may include a metal-based material, a silicon-based material, or a combination thereof. For example, the lateral cylinders LC may be titanium nitride, and the lateral pillar LP may be polysilicon.

Referring to FIG. 11C, the lateral cylinder LC and the lateral pillar LP may be of the same material or different materials. The lateral cylinder LC and the lateral pillar LP may include a metal-based material, a silicon-based material, or a combination thereof. For example, the lateral cylinder LC and the lateral pillar LP may be of titanium nitride. In addition, the lateral cylinder LC may be of titanium nitride and the lateral pillar LP may be of polysilicon.

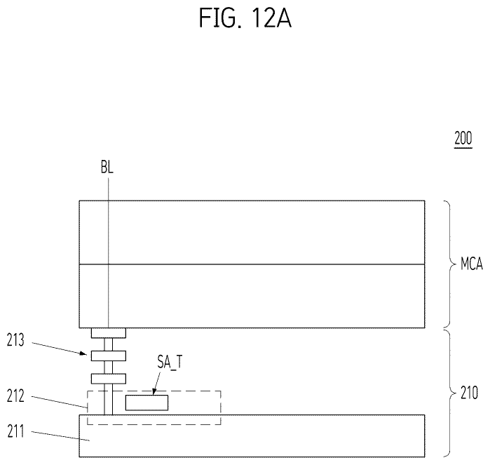

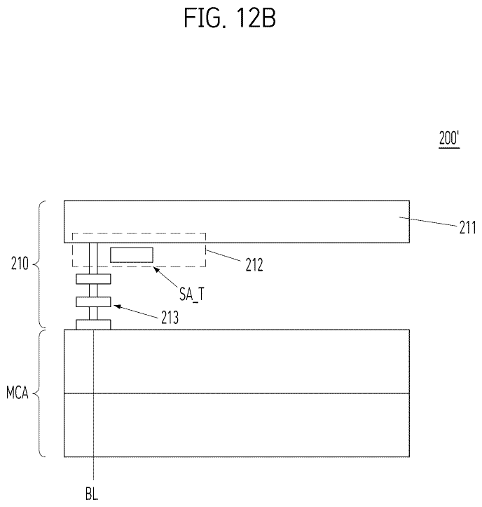

FIGS. 12A and 12B are views illustrating a memory device 200 and 200′ in accordance with another embodiment of the present invention.

Referring to FIGS. 12A and 12B, the memory device 200 and 200′ may include a peripheral circuit portion 210 and a memory cell array stack MCA. The memory cell array stack MCA may be the same as the memory cell array stack MCA of FIG. 1.

Referring to FIG. 12A, the memory cell array stack MCA may be positioned above the peripheral circuit portion 210. The peripheral circuit portion 210 may correspond to the peripheral structure 110 of FIG. 1. Accordingly, the memory device 200 may have a PUC (Peripheral Under Cell) structure.

Referring to FIG. 12B, the memory cell array stack MCA may be positioned below the peripheral circuit portion 210. The peripheral circuit portion 210 may correspond to the peripheral structure 110 of FIG. 1. For example, in FIG. 1, the peripheral structure 110 may be stacked above the memory cell array stack MCA. Thus, the memory device 200′ may have a CUP (Cell under Peripheral) structure.

The peripheral circuit portion 210 may refer to a circuit for driving and controlling the memory cell array stack MCA during a driving operation (including a read or write operation) to a memory. The peripheral circuit portion 210 may include an N-channel transistor, a P-channel transistor, a CMOS circuit, or a combination thereof. The peripheral circuit portion 210 may include an address decoder circuit, a read circuit, and a write circuit. The peripheral circuit portion 210 may have a structure including a semiconductor substrate 211 and a sense amplifier 212 arranged on the surfaces of the semiconductor substrate 211. The sense amplifier 212 may include a transistor SA_T using the semiconductor substrate 211 as a channel. The transistor SA_T may include a planar channel transistor whose channel is parallel to the surface of the semiconductor substrate 211. The transistor structure in the sense amplifier 212 may include a recess channel transistor, a buried gate transistor, and a fin channel transistor (FinFET) in addition to the planar channel transistor.

The bit lines BL of the memory cell array stack MCA may be electrically connected to the transistor SA_T of the sense amplifier 212. The bit lines BL and the transistor SA_T may be coupled to each other through a multi-level metal line MLM 213. The multi-level metal line MLM 213 may be formed by a Damascene process. It is understood that transistor SA_T is described as an example of a plurality of transistors which may be included in the peripheral circuit portion 210.

Although not illustrated, according to another embodiment of the present invention, the memory device 200 and 200′ may include a first semiconductor substrate and a second semiconductor substrate bonded to the first semiconductor substrate. The memory cell array stack MCA may be formed over the first semiconductor substrate, and the peripheral circuit portion 210 may be formed over the second semiconductor substrate. Each of the first semiconductor substrate and the second semiconductor substrate may include conductive bonding pads, and the first semiconductor substrate and the second semiconductor substrate may be bonded to each other through the conductive bonding pads. Thus, the memory cell array stack MCA and the peripheral circuit portion 210 may be electrically connected to each other.

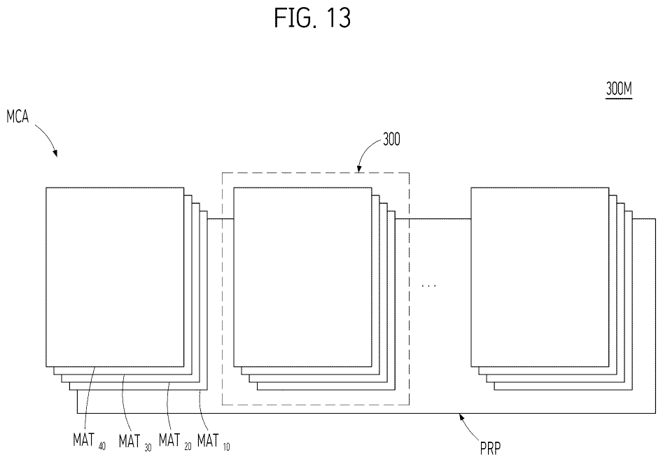

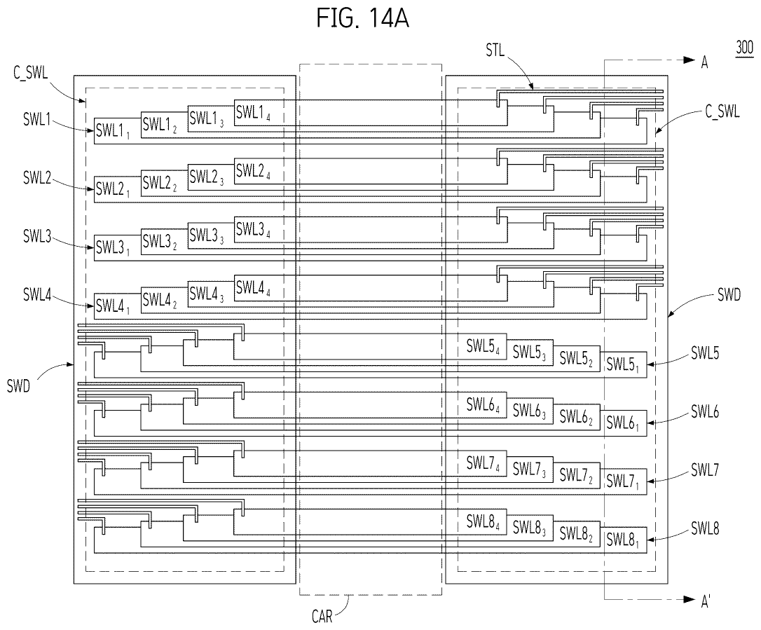

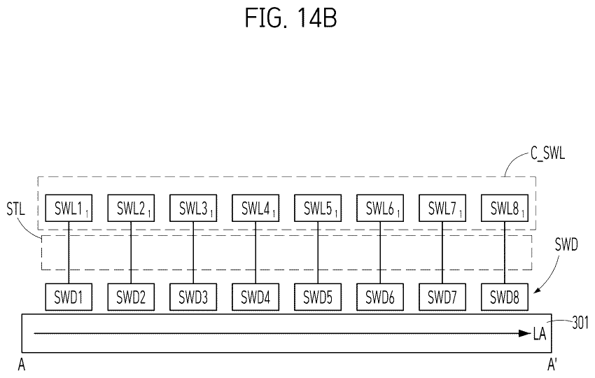

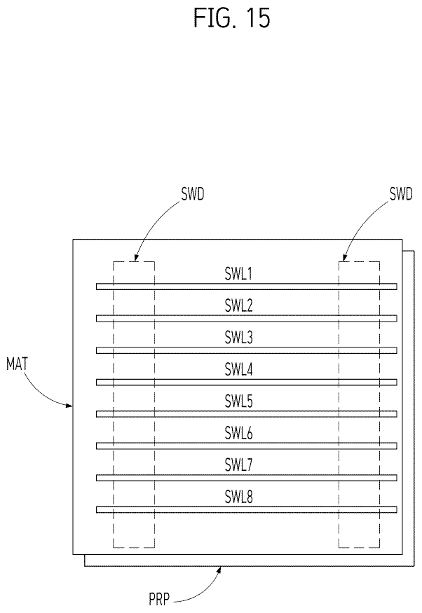

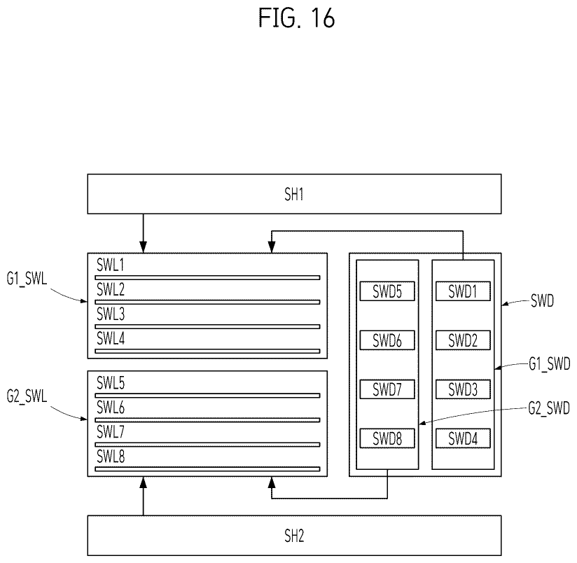

FIG. 13 is a perspective view illustrating a schematic structure of a memory device in accordance with another embodiment of the present invention. FIG. 14A is a view illustrating a portion 300 of FIG. 13. FIG. 14B is a cross-sectional view taken in a line A-A′ of FIG. 14A. FIGS. 15 and 16 illustrate a connection relationship between one memory cell mat and a peripheral circuit portion. The memory device may include a plurality of memory cell mats, and the memory cell mats may be arranged in rows and columns.

Referring to FIG. 13, a memory device 300M may include a plurality of memory cell array stacks MCA1 to MCAn spaced apart at a regular interval along the second direction D2. Each of the memory cell array stacks MCA₁ to MCAₙ may include a plurality of memory cell mats MAT₁₀ to MAT₄₀. The memory cell mats MAT₁₀ to MAT₄₀ in each of the memory cell array stacks MCA₁ to MCAₙ may be stacked vertically in the first direction D1. Each of the memory cell mats MAT₁₀ to MAT₄₀ may be a memory cell array matrix, having a plurality of memory cells arranged in rows and columns along the second and third directions D2 and D3, respectively.

The memory cell mats MAT10 to MAT40 may be positioned above a peripheral circuit portion PRP.

The peripheral circuit portion PRP may be the peripheral circuit portion 210 described earlier. The peripheral circuit portion PRP may include at least one control circuit for controlling the operation of the memory cell array stacks MCA1 to MCAₙ. The at least one control circuit may include a sense amplifier, a sub word line driver circuit SWD, a refresh circuit, a pre-charge circuit, a column address circuit, a row/column repair circuit, a row-column control circuit, a test mode circuit, a data driver circuit, or an analog circuit.

Each of the memory cell mats MAT₁₀ to MAT₄₀ may include a plurality of memory cells that are arranged at the same level (i.e., a horizontal level defined by the second and third directions D2 and D3). In an embodiment, the memory cells may be DRAM memory cells. The memory cells may have the structure described earlier. For example, as described in FIG. 1, each of the memory cells may include a bit line which is vertically oriented at a level higher than the peripheral circuit portion PRP, a plate line which is vertically oriented at a level higher than the peripheral circuit portion PRP, and a transistor and a capacitor between the bit line and the plate line, and word lines of a double structure which are vertically stacked with an active layer of the transistor interposed therebetween.

The word lines WL of the memory cell may be simply referred to as ‘sub word line SWL’. The memory cell mat may be formed vertically from the peripheral circuit portion PRP.

FIG. 14A is a view illustrating the portion 300 of FIG. 13 and shows sub word line stacks SWL1 to SWL8 of the memory cell mats MAT10 to MAT40.

Referring to FIG. 14A, each of the memory cell mats MAT10 to MAT40 may include eight sub word line stacks SWL1 to SWL8. Accordingly, the stacked structure of the memory cell mats MAT₁₀ to MAT40 may be formed of vertically stacked sub word lines. For example, four sub word lines SWL1₁ to SWL1₄ may be vertically stacked in the first sub word line stack SWL1. Four sub word lines SWL2₁ to SWL2₄ may be vertically stacked in the second sub word line stack SWL2. Four sub word lines SWL3₁ to SWL3₄ may be vertically stacked in the third sub word line stack SWL3. Four sub word lines SWL4₁ to SWL4₄ may be vertically stacked in the fourth sub word line stack SWL4. Four sub word line stacks SWL5₁ to SWL5₄ may be vertically stacked in the fifth sub word line stack SWL5. Four sub word lines SWL6₁ to SWL6₄ may be vertically stacked in the sixth sub word line stack SWL6. Four sub word lines SWL7₁ to SWL7₄ may be vertically stacked in the seventh sub word line stack SWL7. Four sub word lines SWL8₁ to SWL8₄ may be vertically stacked in the eighth sub word line stack SWL8. As such, each of the sub word line stacks of the mat may have four layers.

In each sub word line stack, the height may be gradually increased (in a stepwise manner) from the lowest level sub word lines SWL1₁ to SWL8₁ to the highest level sub word lines SWL1₄ to SWL8₄. Eight sub word lines may be laterally arranged at the same level. For example, in FIG. 14A the first sub word lines SWL1₁, SWL2₁, SWL3₁, SWL4₁, SWL5₁, SWL6₁, SWL7₁, and SWL8₁ may be laterally arranged at the lowest level, and the fourth sub word lines SWL1₄, SWL2₄, SWL3₄, SWL4₄, SWL5₄, SWL6₄, SWL7₄, SWL8₄ may be laterally arranged at the highest level. The length of the sub word lines which are positioned at the same layer may be the same. The length of the sub word lines may decrease in a stepwise manner from the lowest level to the highest level creating multi-step end structures. As illustrated in FIG. 14A the multi step end structures may be formed at both opposite ends of the mat along the second direction D2 which symmetrical with respect to an axis of symmetry extending in the third direction D3 and crossing through a center point of the mat.

One-side end of each sub word line stack may be simply referred to as a word line contact region C_SWL. The word line contact region C_SWL may include the multi-step end structures of all the sub word line stacks. Hence, in the embodiment of FIG. 14A, there may be a left and a right word line contact region C_SWL corresponding to the opposite side step end structures of the mat. The sub word line driver circuit SWD may be positioned underneath the word line contact region C_SWL. Each of the sub word lines SWL1₁ to SWL8₁ may be electrically connected to the sub word line driver circuit SWD through an interconnection STL. Each of the memory cell mats MAT₁₀ to MAT₄₀ may include the word line contact region C_SWL and cell array region CAR.

Referring to FIG. 14B, a sub word line driver circuit SWD may be formed over the substrate 301. The sub word line driver circuit SWD may include a plurality of sub word line drivers SWD1 to SWD8. The sub word line drivers SWD1 to SWD8 may be coupled to a corresponding one of the sub word lines SWL1₁ to SWL8₁ through a corresponding one of the interconnections STL.

The sub word lines SWL1₁ to SWL8₁ may be laterally arranged at a same level (see reference numeral ‘LA’). The sub word lines SWL1₁ to SWL8₁ may be disposed over the sub word line drivers SWD1 to SWD8. The sub word line stacks SWL1 to SWL8 may be vertically arranged above the sub word line drivers SWD1 to SWD8, i.e., the SWL1₁ above the SWD1, the SWL2₁ above the SWD2, the SWL3₁ above the SWD3, the SWL4₁ above the SWD4, the SWL5₁ above the SWD5, the SWL6₁ above the SWD6, the SWL7₁ above the SWD7, and the SWL8₁ above the SWD8.

FIG. 15 is a detailed view illustrating one memory cell mat e.g., MAT₁₀ and a peripheral circuit portion PRP corresponding to the memory cell mat MAT₁₀.

Referring to FIG. 15, the memory cell mat MAT₁₀ may include a plurality of sub word lines arranged in stacks. For example, the memory cell mat MAT₁₀ may include eight sub word line stacks SWL1 to SWL8. The sub word line stacks SWL1 to SWL8 may each include a plurality of sub word lines having a double word line structure, for example the double word line structure of FIG. 5. Hereinafter, for the sake of convenience in description, the sub word lines in the sub word line stacks SWL1 to SWL8 are illustrated as single sub word lines.

The peripheral circuit portion PRP may include a sub word line driver circuit SWD. The sub word line driver circuit SWD may be disposed underneath the memory cell mat MAT. For example, the sub word line driver circuit SWD may be disposed underneath both-side ends of the memory cell mat MAT₁₀.

Hereinafter, for the sake of convenience in description, the sub word line driver circuit SWD is illustrated only on the right side of the memory cell mat MAT₁₀.

FIG. 16 illustrates a connection relationship between one memory cell mat and a peripheral circuit portion. The connection relationship between the sub word lines and the sub word line driver is described by taking an example of the lowest level sub word lines SWL1₁ to SWL8₁. Hereinafter, for the sake of convenience in description, the lowest level sub word lines are denoted by ‘SWL1 to SWL8’.

Referring to FIG. 16, the sub word lines SWL1 to SWL8 may be defined as first and second sub word line groups G1_SWL and sub word line group G2_SWL. The first sub word line group G1_SWL may include four sub word lines SWL1 to SWL4, and the second sub word line group G2_SWL may include four sub word lines SWL5 to SWL8. According to another embodiment of the present invention, the first sub word line group G1_SWL may include odd sub word lines Odd SWL, which are SWL1, SWL3, SWL5, and SWL7, and the second sub word line group G2_SWL may include even sub word lines Even SWL, which are SWL2, SWL4, SWL6, and SWL8.

The peripheral circuit portion PRP may include at least one or more control circuits. The peripheral circuit portion PRP may include a plurality of sub word line driver circuits SWD. Each of the sub word line driver circuits SWD may include a first and a second sub word line driver circuit group G1_SWD and G2_SWD. The first sub word line driver circuit group G1_SWD may be a circuit for controlling the first sub word line group G1_SWL. The second sub word line driver circuit group G2_SWD may be a circuit for controlling the second sub word line group G2_SWL.

The first sub word line driver circuit group G1_SWD may include a plurality of sub word line drivers SWD1 to SWD4 for driving the sub word lines SWL1 to SWL4. The second sub word line driver circuit group G2_SWD may include a plurality of sub word line drivers SWD5 to SWD8 for driving the sub word lines SWL5 to SWL8. For example, the first to fourth sub word lines SWL1 to SWL4 may be driven by the first to fourth sub word line drivers SWD1 to SWD4, respectively. The fifth to eighth sub word lines SWL5 to SWL8 may be driven by the fifth to eighth sub word line drivers SWD5 to SWD8, respectively.

The peripheral circuit portion PRP may further include a plurality of sub-hole circuits SH1 to SH2. The sub-hole circuits SH1 to SH2 may be circuits for controlling the first and second sub word line driver groups G1_SWD and G2_SWD. The sub-hole circuits SH1 to SH2 may be disposed underneath the memory cell mat MAT. The sub-hole circuits SH1 to SH2 may be disposed along two opposite sides of the cell mat MAT. The sub word line drivers SWD1 to SWD4 may horizontally arranged along a direction perpendicular to the sub word lines SWL1 to SWL4. The sub word line drivers SWD5 to SWD8 may horizontally arranged along a direction perpendicular to the sub word lines SWL5 to SWL8.

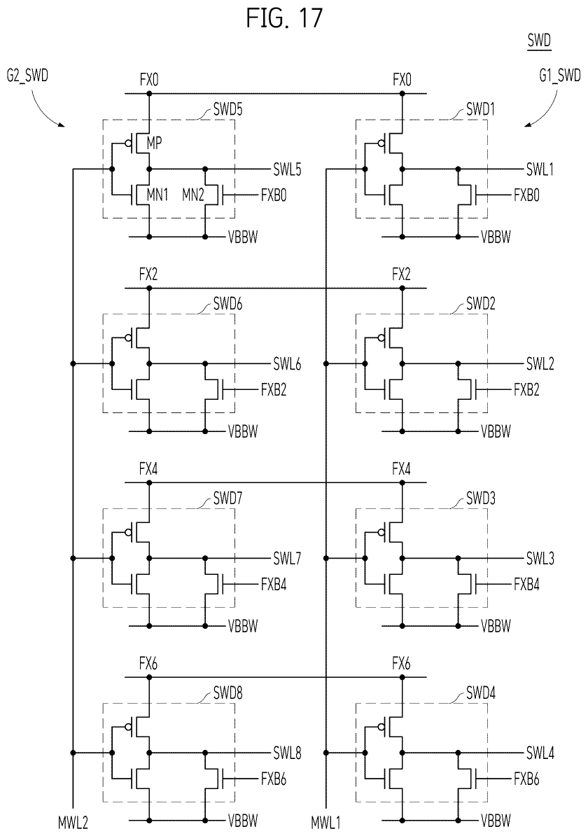

FIG. 17 is an equivalent circuit diagram illustrating the sub word line driver circuit SWD of FIG. 16.

Referring to FIG. 17, the sub word line driver circuit SWD may include the first sub word line driver circuit group G1_SWD and the second sub word line driver circuit group G2_SWD. The first sub word line driver circuit group G1_SWD may include four sub word line drivers SWD1, SWD2, SWD3, and SWD4. The second sub word line driver circuit group G2_SWD may include four sub word line drivers SWD5, SWD6, SWD7, and SWD8.

The four sub word line drivers SWD1, SWD2, SWD3, and SWD4 of the first sub word line driver circuit group G1_SWD may be driven in response to a first main word line MWL1. Four sub word line drivers SWD5, SWD6, SWD7, and SWD8 of the second sub word line driver circuit group G2_SWD may be driven in response to a second main word line MWL2. The sub word line drivers SWD1 to SWD8 may be activated by first sub word line driver enable signals FX0, FX2, FX4, and FX6 and second sub word line driver enable signals FXB0, FXB2, FXB4, and FXB6. The activated sub word line drivers SWD1 to SWD8 may drive the sub word lines SWL1 to SWL8, respectively. The first sub word line driver circuit group G1_SWD and the second sub word line driver circuit group G2_SWD may receive the first sub word line driver enable signals FX0, FX2, FX4, and FX6 and the second sub word line driver enable signals FXB0, FXB2, FXB4, and FXB6 in common.

The second sub word line driver enable signals FXB0 to FXB6 may be inverted signals of the first sub word line driver enable signals FX0 to FX6. The first sub word line driver enable signals FX0 to FX6 and the second sub word line driver enable signals FXB0 to FXB6 may be provided from the first sub-hole circuits SH1 and SH2 (shown in FIG. 16).

Each of the sub word line drivers SWD1 to SWD8 may include one PMOSFET MP and two NMOSFETs MN1 and MN2.

Hereafter, the sub word line driver SWD5 will be taken as an example and described. In the sub word line driver SWD5, the gates of the PMOSFET MP and the NMOSFET MN1 are coupled to the second main word line MWL2, and the drains of the PMOFET MP and the NMOSFETs MN1 and MN2 are coupled to the sub word line SWL5. The first sub word line driver enable signal FX0 is applied to the source of the PMOSFET MP. The second sub word line driver enable signal FXB0 is applied to the gate of the NMOSFET MN2. A ground voltage VBBW is supplied to the sources of the NMOSFETs MN1 and MN2.

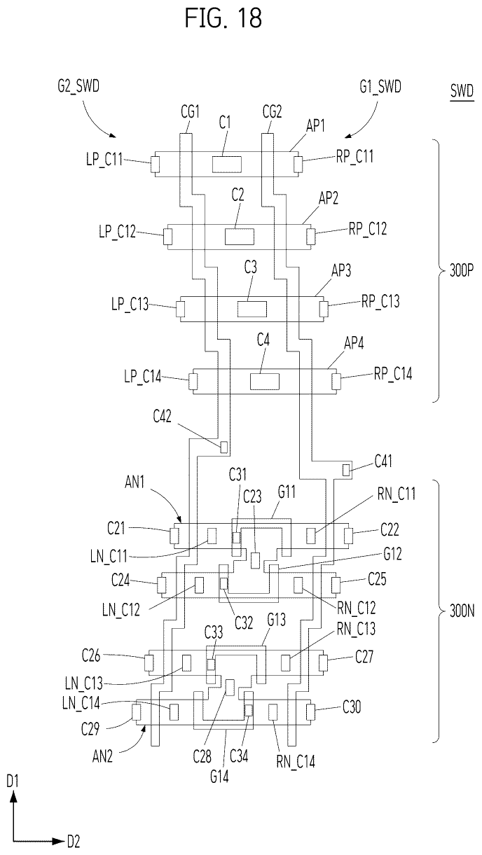

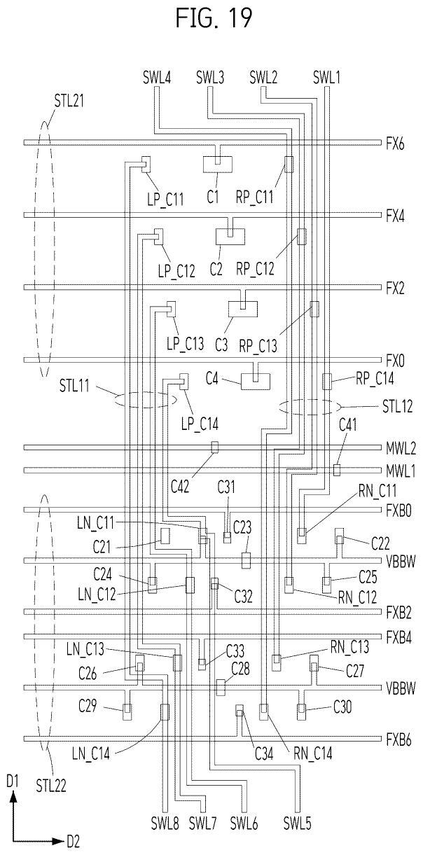

FIG. 18 is a layout illustrating the sub word line driver circuit SWD of FIG. 17. FIG. 19 is a view illustrating interconnections coupled to the contacts of FIG. 18. Among the constituent elements shown in FIG. 18, only the interconnections and contacts are illustrated and described while the other constituent elements except for the contacts are omitted.

Referring to FIGS. 18 and 19, the first and second groups of the sub word line driver circuits G1_SWDL and G2_SWD may include a PMOSFET region 300P and an NMOSFET region 300N, individually. A plurality of active regions AP1 to AP4, AN1, and AN2 may be disposed in the PMOSFET region 300P and the NMOSFET region 300N. In this case, the first active regions AP1 to AP4 of the PMOSFET region 300P may be spaced apart from each other in a bar shape with a predetermined distance. The second active regions AN1 and AN2 of the NMOSFET region 300N may be formed in the shape of an ‘H’ in which the central portions of two neighboring sub active regions are coupled to each other. The first and second group sub word line driver circuits G1_SWDL and G2_SWD may share the first active regions AP1 to AP4 of the PMOSFET region 300P, and share the second active regions AN1 and AN2 of the NMOSFET region 300N.

The gates G1 and G2 which extend in the first direction D1 may be disposed over the first active regions AP1 to AP4 of the PMOSFET region 300P and the second active regions AN1 and AN2 of the NMOSFET region 300N. In this case, the gates G1 and G2 may be formed to have different line widths in the PMOSFET region 300P and the NMOSFET region 300N. For example, in the gates G1 and G2, the line width of a portion crossing the first active regions AP1 to AP4 of the PMOSFET region 300P may be formed greater than the line width of a portion crossing the second active regions AN1 and AN2 of the NMOSFET region 300N.

Among the gates G1 and G2, the second gate CG2 may be coupled to the first main word line MWL1 for driving the first group sub word line driver G1_SWD, and the first gate CG1 may be coupled to the second main word line MWL2 for driving the second group sub word line driver G2_SWD. The gates CG1 and CG2 may extend along a direction perpendicular to the sub-word lines SWL1 to SWL8.

Selection gates G11, G12, G13, and G14 may be disposed over the second active regions AN1 and AN2 of the NMOSFET region 300N. The selection gates G11 to G14 may be disposed between the first gate CG1 and the second gate CG2, and the selection gates G11 to G14 may receive the second sub word line enable signals FXB0, FXB2, FXB4, and FXB6, respectively.

First contacts C₁ to C₄ coupled to the first sub word line driver enable signals FX0, FX2, FX4, and FX6 and second contacts LP_C11 to LP_C14 and RP_C11 to RP_C14 for connection to sub word lines SWL1 to SWL8 may be disposed in the first active regions AP1 to AP4 of the PMOSFET region 300P. The first contacts C₁ to C₄ may be disposed in the central portion of the first active regions AP1 to AP4 between the first gate CG1 and the second gate CG2. The second contacts LP_C11 to LP_C14 and RP_C11 to RP_C14 may be positioned at both-side ends of the first active regions AP1 to AP4.

Third contacts LN_C11 to LN_C14 and RN_C11 to RN_C14 coupled to the sub word lines SWL1 to SWL8 and fourth contacts C21 to C30 coupled to the ground voltage VBBW may be disposed in the second active regions AN1 and AN2. The third contacts LN_C11 to LN_C14 may be disposed in a portion of the second active regions AN1 and AN2 between the first gate CG1 and the selection gates G11 to G14, and the third contacts RN_C11 to RN_C14 may be disposed between the second gate CG2 and the selection gates G11 to G14. Portions C21, C22, C24, C25, C26, C27, C29, and C30 of the fourth contacts C21 to C30 may be disposed on both-side edges of the second active regions AN1 and AN2. Also, portions C23 and C28 of the fourth contacts C21 to C30 may be disposed in the center of the second active regions AN1 and AN2, that is, between the neighboring selection gates G11, G12, G13, and G14.

Fifth contacts C31 to C34 that receive the second sub word line driver enable signals FXB0 to FXB6 may be disposed over the selection gates G11 to G14.

A sixth contact C41 coupled to the first main word line MWL1 may be disposed over the second gate CG2, and a sixth contact C42 coupled to the second main word line MWL2 may be disposed over the first gate CG1.

FIG. 19 illustrates an interconnection coupled to each of the contacts shown in FIG. 18 and describes only the interconnection and contacts while omitting the other constituent elements among the constituent elements shown in FIG. 18.

Referring to FIGS. 17 to 19, the sub word lines SWL1 to SWL8 may be respectively coupled to the drains of the PMOFET MP and the NMOSFETs MN1 and

MN2 through the first interconnections STL11 and STL12. The first and second sub word line driver enable signals FX0 to FX6 and FXB0 to FXB6 and the ground voltage VBBW may be applied through the second interconnections STL21 and STL22. The sub word line drivers SWD1 to SWD8 may be coupled to the sub word lines SWL1 to SWL8 through the first interconnections STL11 and STL12.

The first and second interconnections STL11, STL12, STL21, and STL22 may have a multi-layer level structure. In the multi-layer level structure, first interconnections STL11 and STL12 may be positioned at a lower level, and second interconnections STL21 and STL22 may be positioned at a higher level than the first interconnections STL11 and STL12. The first interconnections STL11 and STL12 and the second interconnections STL21 and STL22 may include metal-based materials such as tungsten, aluminum, and copper. The first interconnections STL11 and STL12 and the second interconnections STL21 and STL22 may be individually referred to as metal lines. Therefore, the first interconnections STL11 and STL12 and the second interconnections STL21 and STL22 may be referred to as multi-layer level metal lines MLMs. The first interconnections STL11 and STL12 may include a plurality of first interconnection lines, and the first interconnection lines may be spaced apart from each other and extend in the first direction D1. The second interconnections STL21 and STL22 may include a plurality of second interconnection lines, and the second interconnection lines may be spaced apart from each other and extend in the second direction D2.

The first interconnections STL11 and STL12 may couple the sub word lines SWL1 to SWL8 and the sub word line drivers SWD1 to SWD8 to each other. The second interconnections STL21 and STL22 may couple the first and second sub-hole circuits SH1 and SH2 and the sub word line drivers SWD1 to SWD8 to each other.

The first interconnections STL11 and STL12 may be coupled to the sub word line drivers SWD1 to SWD8 through the second contacts LP_C11 to LP_C14 and RP_C11 to RP_C14 and the third contacts LN_C11 to LN_C14 and RN_C11 to RN_C14. For example, the sub word line drivers SWD1 to SWD4 may be coupled to the sub word line SWL1 to SWL4 through the second contacts RP_C11 to RP_C14 and the third contacts RN_C11 to RN_C14. The sub word line drivers SWD5 to SWD8 may be coupled to the sub word line SWL5 to SWL8 through the second contacts LP_C11 to LP_C14 and the third contacts LN_C11 to LN_C14.

The second interconnections STL21 and STL22 may be coupled to the sub word line drivers SWD1 to SWD8 through the first contacts C1 to C4 and the fourth contacts C21 to C30.

The first and second main word lines MWL1 and MWL2 may be positioned at a higher level than the second interconnections STL21 and STL22. The first and second main word lines MWL1 and MWL2 may be referred to as third interconnections. The first interconnections STL11 and STL12 may extend in the first direction D1. The second interconnections STL21 and STL22 may extend in the second direction D2. The first and second main word lines MWL1 and MWL2 may extend in the second direction D2. A portion of the first interconnections STL11 and STL12 may have a bending structure.

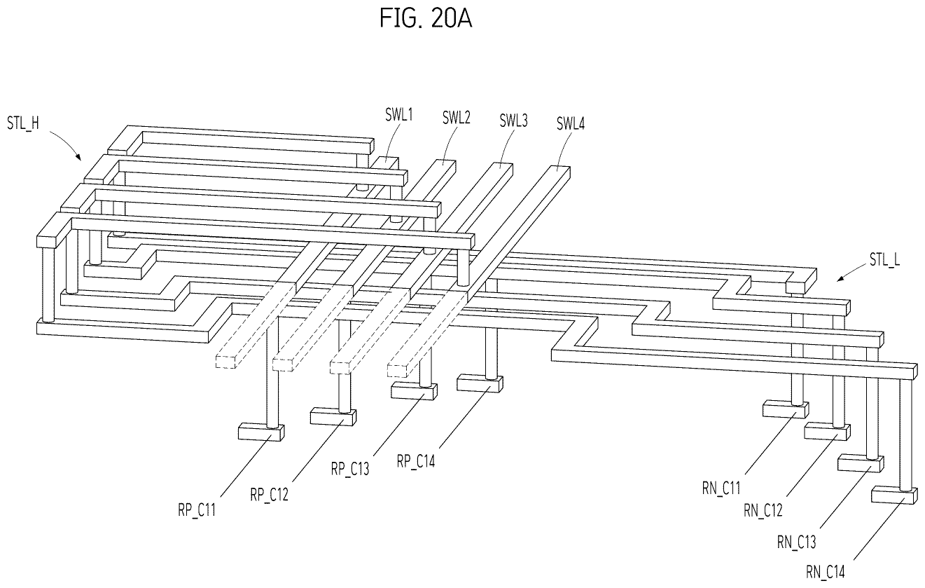

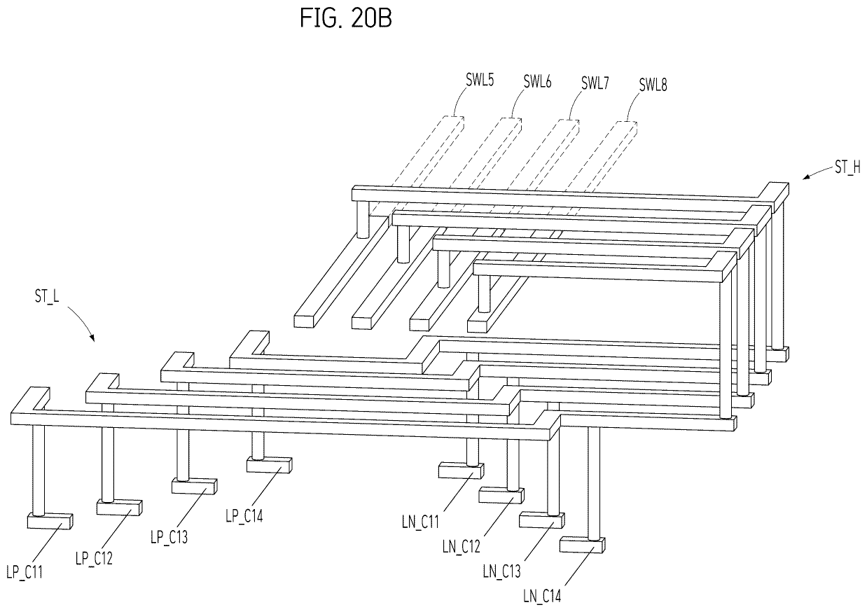

FIG. 20A is a perspective view illustrating a connection relationship between a first group sub word line and the first group sub word line driver circuit. FIG. 20B is a perspective view illustrating a connection relationship between a second group sub word line and the second group sub word line driver circuit.

Referring to FIG. 20A, the first group sub word lines SWL1, SWL2, SWL3, and SWL4 may be coupled to the contacts RP_C11 to RP_C14 and RN_C11 to RN_C14 of the first sub word line driver group G1_SWD through the multi-layer level interconnections STL_L and STL_H.

Referring to FIG. 20B, the second group sub word line stacks SWL5, SWL6, SWL7, and SWL8 may be coupled to the contacts LP_C11 to LP_C14 and LN_C11 to LN_C14 of the second group sub word line driver G2_SWD through the multi-layer level interconnections STL_L and STL_H.

The multi-layer level interconnections STL_L and STL_H may include a low-level interconnection STL_L and a high-level interconnection STL_H. The low-level interconnection STL_L may be positioned underneath the high-level interconnection STL_H. The low-level interconnection STL_L and the high-level interconnection STL_H may include vias and metal lines, individually.

The multi-layer level interconnections STL_L and STL_H may correspond to the first interconnections STL11 and STL12 of FIG. 19. The multi-layer level interconnections STL_L and STL_H may be referred to as strapping units.

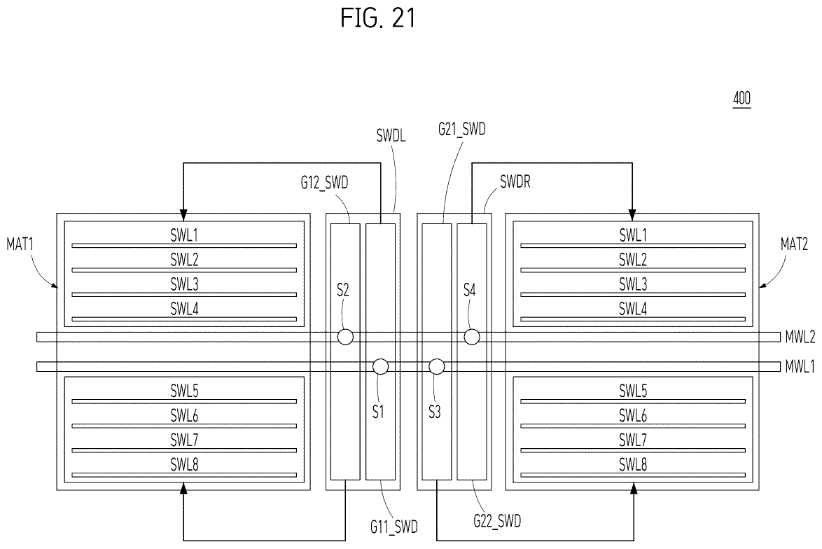

FIG. 21 is a schematic diagram illustrating a memory device in accordance with another embodiment of the present invention.

Referring to FIG. 21, the memory device 400 may include a plurality of memory cell mats MAT1 and MAT2. The memory cell mats MAT1 and MAT2 may be arranged in a row direction and may include a first memory cell mat MAT1 and a second memory cell mat MAT2. A pair of sub word line driver circuits SWDL and SWDR may be disposed between the first memory cell mat MAT1 and the second memory cell mat MAT2. In other words, the first and second sub word line driver circuits SWDL and SWDR may be disposed between the first memory cell mat MAT1 and the second memory cell mat MAT2. For the sake of convenience in description, the first and second sub word line driver circuits SWDL and SWDR are illustrated to be disposed between the first memory cell mat MAT1 and the second memory cell mat MAT2. However, the first and second sub word line driver circuits SWDL and SWDR may be positioned underneath the one-side ends of the first memory cell mat MAT1 and the second memory cell mat MAT2, respectively. The first sub word line driver circuit SWDL may be positioned underneath the one-side end of the first memory cell mat MAT1, and the second sub word line driver circuit SWDR may be positioned underneath the one-side end of the second memory cell mat MAT2. The first sub word line driver circuit SWDL and the second sub word line driver circuit SWDR may be symmetrical to each other between the first memory cell mat MAT1 and the second memory cell mat MAT2.

The first memory cell mat MAT1 may include a plurality of sub word lines SWL1 to SWL8. The second memory cell mat MAT2 may include a plurality of sub word lines SWL1 to SWL8. The first sub word line driver circuit SWDL may be positioned underneath ends of the sub word lines SWL1 to SWL8 of the first memory cell mat MAT1. The sub word line driver circuit SWDR may be positioned underneath the ends of the sub word lines SWL1 to SWL8 of the second memory cell mat MAT2.

The first sub word line driver circuit SWDL may include first and second sub word line driver circuit groups G11_SWD and G12_SWD. The second sub word line driver circuit SWDR may include first and second sub word line driver circuit groups G21_SWD and G22_SWD.

The first and second groups of the sub word line driver circuits G11_SWD, G12_SWD, G21_SWD, and G22_SWD may be the same as those of FIGS. 17 to 19, respectively. The first and second groups of the sub word line drivers G11_SWD and G12_SWD may be coupled to the sub word lines SWL1 to SWL8 of the first memory cell mat MAT1. The first and second group sub word line driver circuits G21_SWD and G22_SWD may be coupled to the sub word lines SWL1 to SWL8 of the second memory cell mat MAT2. Each of the first and second groups of the sub word line driver circuits G11_SWD, G12_SWD, G21_SWD, and G22_SWD may include four sub word line drivers.

The first sub word line driver circuit group G11_SWD may drive the sub word line stacks SWL1 to SWL4 of the first memory cell mat MAT1. The second sub word line driver circuit group G12_SWD may drive the sub word line stacks SWL5 to SWL8 of the first memory cell mat MAT1. The first sub word line driver circuit group G21_SWD may drive the sub word line stacks SWL5 to SWL8 of the second memory cell mat MAT2. The second sub word line driver circuit group G22_SWD may drive the sub word line stacks SWL1 to SWL4 of the second memory cell mat MAT2.

The first sub word line driver circuit group G11_SWD may be coupled to the first main word line MWL1 through a contact S1. The second sub word line driver circuit group G12_SWD may be coupled to the second main word line MWL2 through a contact S2. The first sub word line driver circuit group G11_SWD may be activated by the first main word line MWL1 and may drive the sub word lines SWL1 to SWL4 of the first memory cell mat MAT1. The sub word lines SWL1 to SWL4 may be referred to as first group horizontal level sub word lines. The second sub word line driver circuit group G12_SWD may be activated by the second main word line MWL2 and may drive the sub word lines SWL5 to SWL8 of the first memory cell mat MAT1. The sub word lines SWL5 to SWL8 may be referred to as second group horizontal level sub word lines.

The first sub word line driver circuit group G21_SWD may be coupled to the first main word line MWL1 through a contact S3, and the second sub word line driver circuit group G22_SWD may be coupled to the second main word line MWL2 through a contact S4. The first sub word line driver circuit group G21_SWD may be activated by the first main word line MWL1 and may drive the sub word lines SWL5 to SWL8 of the second memory cell mat MAT2. The sub word lines SWL5 to SWL8 may be referred to as second group horizontal level sub word lines. The second sub word line driver circuit group G22_SWD may be activated by the second main word line MWL2 and may drive the sub word lines SWL1 to SWL4 of the second memory cell mat MAT2. The sub word lines SWL1 to SWL4 may be referred to as first group horizontal level sub word lines.

As described above, the first group horizontal level sub word lines SWL1 to SWL4 of the first memory cell mat MAT1 and the second group horizontal level sub word lines SWL5 to SWL8 of the second memory cell mat MAT2 may be simultaneously driven by the first main word line MWL1. Also, the second group horizontal level sub word lines SWL5 to SWL8 of the first memory cell mat MAT1 and the first group horizontal level sub word lines SWL1 to SWL4 of and the second memory cell mat MAT2 may be simultaneously driven by the second main word line MWL2.

Hereinafter, the sub word line driver circuits of the subsequent embodiments of the present invention may be the same as those of FIG. 21.

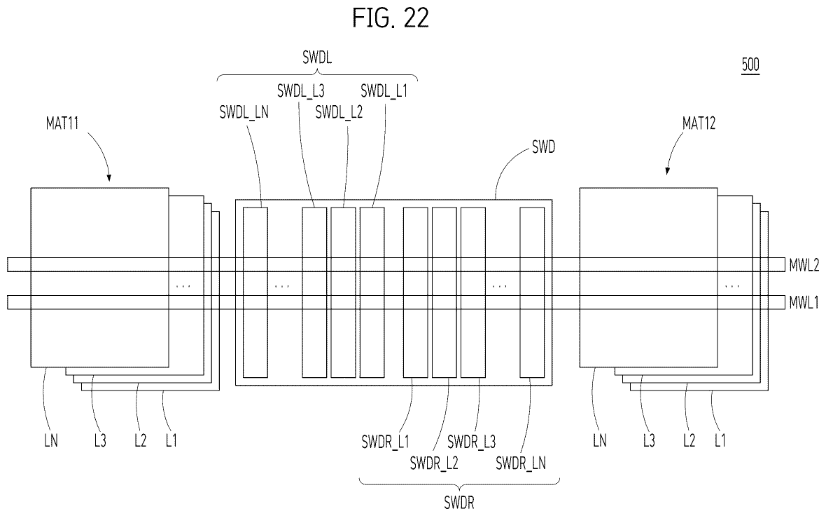

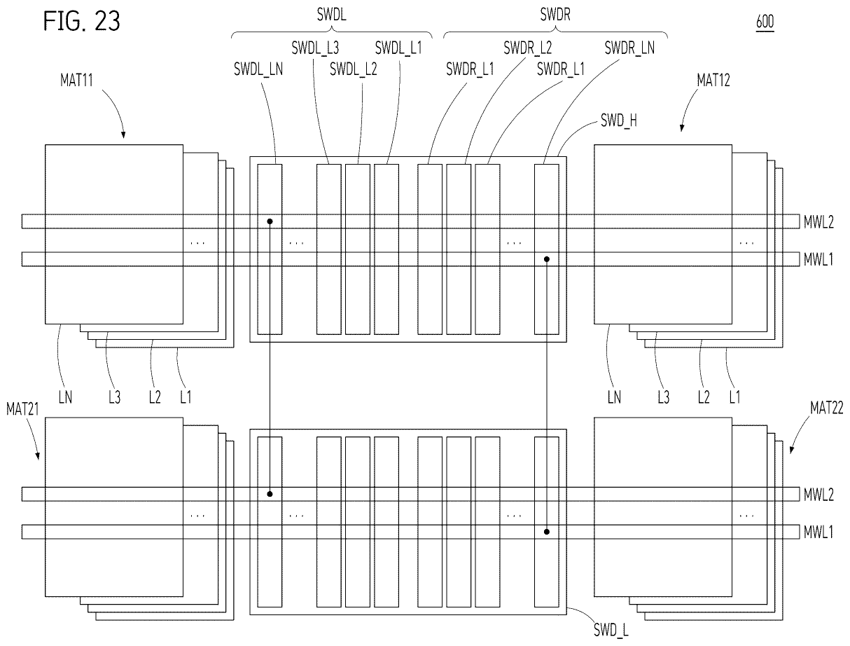

FIGS. 22 and 23 are schematic views illustrating a memory device in accordance with another embodiment of the present invention. The memory device of FIG. 22 may be driven by a 1:8 coding scheme, and the memory device of FIG. 23 may be driven by a 1:16 coding scheme.

Referring to FIG. 22, the memory device 500 may include a plurality of memory cell mats MAT11 and MAT12. The memory cell mats MAT11 and MAT12 may be arranged in a row direction and may include a first memory cell mat MAT11 and a second memory cell mat MAT12.

Each of the first and second memory cell mats MAT11 and 12 may include a multi-layer level memory cell mat. In other words, the first and second memory cell mats MAT11 and 12 may include sub word lines of the multi-layer levels L1 to LN. The sub word lines may gradually increase in height from the lowest level L1 to the highest level LN. At each level, a plurality of sub word lines may be arranged in a horizontal arrangement. For example, as shown in FIG. 21, eight sub word lines SWL1 to SWL8 may be arranged in a horizontal arrangement at each level.

The sub word line driver circuit SWD may be disposed between the first memory cell mat MAT11 and the second memory cell mat MAT12. The sub word line driver circuit SWD may include first and second sub word line driver circuits SWDL and SWDR. For the sake of convenience in description, the first and second sub word line driver circuits SWDL and SWDR are illustrated to be disposed between the first memory cell mat MAT11 and the second memory cell mat MAT12. However, the first and second sub word line driver circuits SWDL and SWDR may be positioned underneath the one-side ends of the first memory cell mat MAT11 and the second memory cell mat MAT12, respectively. The first sub word line driver circuit SWDL may be positioned underneath the one-side end of the first memory cell mat MAT11, and the second sub word line driver circuit SWDR may be positioned underneath the one-side ends of the second memory cell mat MAT12. The first sub word line driver circuit SWDL and the second sub word line driver circuit SWDR may be symmetrical to each other between the first memory cell mat MAT11 and the second memory cell mat MAT12. The first sub word line driver circuit SWDL may drive the sub word lines of the first memory cell mat MAT11, and the second sub word line driver circuit SWDR may drive the sub word lines of the second memory cell mat MAT12.

The first sub word line driver circuit SWDL may include first horizontal level sub word line driver circuits SWDL_L1 to SWDL_LN. The first horizontal level sub word line driver circuits SWDL_L1 to SWDL_LN may refer to a plurality of sub word line driver circuits that are laterally arranged. The first horizontal level sub word line driver circuits SWDL_L1 to SWDL_LN may drive the multi-layer level sub word lines. For example, the first horizontal level sub word line driver circuit SWDL_L1 may drive the sub word lines of the lowest level L1. The first horizontal level sub word line driver circuit SWDL_LN may drive the sub word lines of the highest level LN. As such, the first horizontal level sub word line driver circuit SWDL_L1 to SWDL_LN may be formed to correspond to the sub word lines of each layer. The first horizontal level sub word line driver circuit SWDL_L1 for driving the sub word lines of the lowest level L1 may be disposed in the center of the sub word line driver circuit SWD. The first horizontal level sub word line driver circuit SWDL_LN for driving the sub word lines of the highest level LN may be positioned at an edge of the sub word line driver circuit SWD. The first horizontal level sub word line driver circuit SWDL_LN is disposed closer to the first memory cell mat MAT11 than the first horizontal level sub word line driver circuit SWDL_L1. That is, as the number of sub word lines in the sub word line stack increases, the sub word line driver circuits may be disposed closer to the first memory cell mat MAT11.

The second sub word line driver circuit SWDR may include second horizontal level sub word line driver circuits SWDR_L1 to SWDR_LN. The second horizontal level sub word line driver circuits SWDR_L1 to SWDR_LN may refer to a plurality of sub word line driver circuits that are laterally arranged. The second horizontal level sub word line driver circuits SWDR_L1 to SWDR_LN may drive the sub word lines of multi-layer levels L1 to LN. For example, the second horizontal level sub word line driver circuit SWDR_L1 may drive the sub word lines of the lowest level L1, and the second horizontal level sub word line driver circuit SWDR_LN may drive the sub word lines of the highest level LN. As such, the second horizontal level sub word line driver circuit SWDR_L1 to SWDR_LN may be formed to correspond to the sub word lines of each layer. The second horizontal level sub word line driver circuit SWDR_L1 for driving the sub word lines of the lowest level L1 may be disposed in the center of the sub word line driver circuit SWD. The second horizontal level sub word line driver circuit SWDR_LN for driving the sub word lines of the highest level LN may be positioned at an edge of the sub word line driver circuit SWD. The second horizontal level sub word line driver circuit SWDR_LN is disposed closer to the second memory cell mat MAT12 than the second horizontal level sub word line driver circuit SWDR_L1. That is, as the number of sub word lines in the sub word line stack increases, the sub word line driver circuits may be disposed closer to the second memory cell mat MAT12.

Each of the first and second horizontal level sub word line driver circuits SWDL_L1 to SWDL_LN and SWDR_L1 to SWDR_LN may include the first and second group sub word line driver circuits G11_SWD, G12_SWD, G21_SWD, and G22_SWD, as shown in FIG. 21.

The sub word lines at each level among the sub word lines of the multi-layer levels L1 to LN may be driven by the method described with reference to FIG. 21.

Referring to FIG. 23, a memory device 600 may include a plurality of memory cell mats MAT11, MAT12, MAT21, and MAT22. The memory cell mats MAT11, MAT12, MAT21, and MAT22 may be arranged in a row direction and a column direction, and may include four memory cell mats MAT11, MAT12, MAT21, and MAT22.

Each of the memory cell mats MAT11, MAT12, MAT21, and MAT22 may be a multi-layer level memory cell mat. Accordingly, each of the memory cell mats MAT11, MAT12, MAT21, and MAT22 may include sub word lines of the multi-layer levels L1 to LN. The sub word lines may gradually increase in height from the lowest level L1 to the highest level LN. At each level, a plurality of sub word lines may be arranged in a horizontal arrangement. For example, as shown in FIG. 21, eight sub word lines SWL1 to SWL8 may be arranged in a horizontal arrangement at each level.

A sub word line driver circuit SWD_H may be disposed between the first memory cell mat MAT11 and the second memory cell mat MAT12. The sub word line driver circuit SWD_H may include first and second sub word line driver circuits SWDL and SWDR. A sub word line driver circuit SWD_L may be disposed between a third memory cell mat MAT21 and a fourth memory cell mat MAT22. The sub word line driver circuit SWD_L may include first and second sub word line driver circuits SWDL and SWDR in the same manner as the sub word line driver circuit SWD_H. The sub word line driver circuits SWD_H and SWD_L may be the same as the sub word driver circuit SWD of FIG. 22.

In the memory device 600 of FIG. 23, the sub word line driver circuits SWD_H and SWD_L of the two memory cell mats MAT11 and MAT21 in the column direction may share the first and second main word lines MWL1 and MWL2. Accordingly, the sub word lines may be driven by the 1:16 coding scheme. In other words, 16 sub word line drivers may be activated by one main word line, thereby driving 16 sub word lines.

In order to share the first and second main word lines MWL1 and MWL2 with each other, for example, gates of the sub word line drivers neighboring in a column direction may be coupled to each other.

According to some embodiments of the present invention, the first and second sub-hole circuits SH1 and SH2 may be disposed over the substrate to overlap with a memory cell mat. In other words, other than the structure in which the first and second sub-hole circuits SH1 and SH2 are positioned between the upper memory cell mat and the lower memory cell mat, the first and second sub-hole circuits SH1 and SH2 may be positioned underneath each memory cell mat.

According to the embodiments of the present invention described above, the net die may be increased by arranging the sub word line driver circuits underneath the memory cell mat.

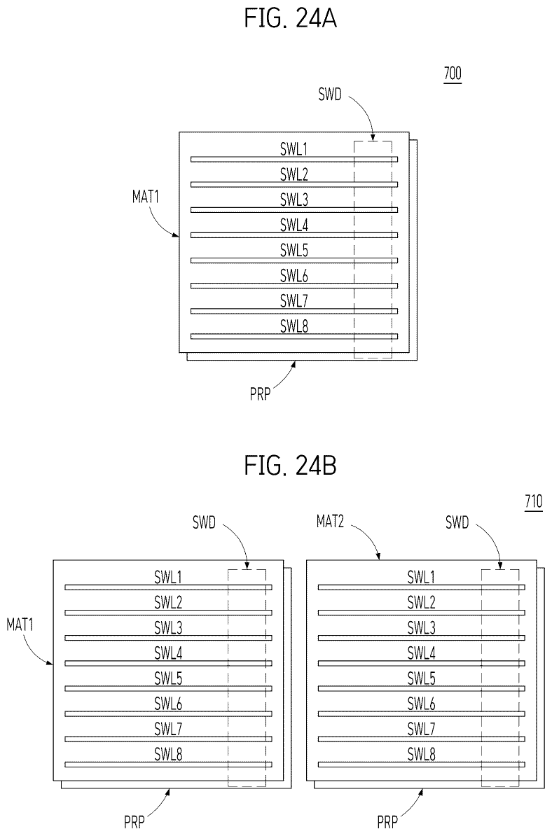

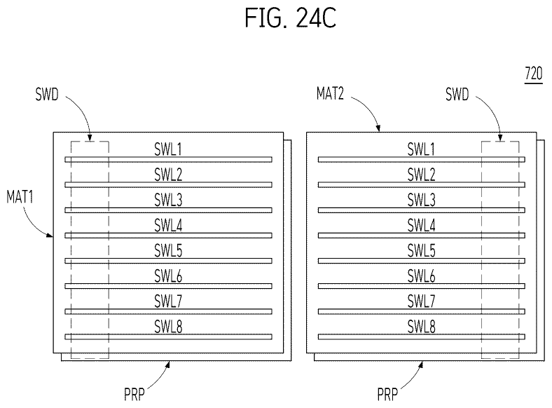

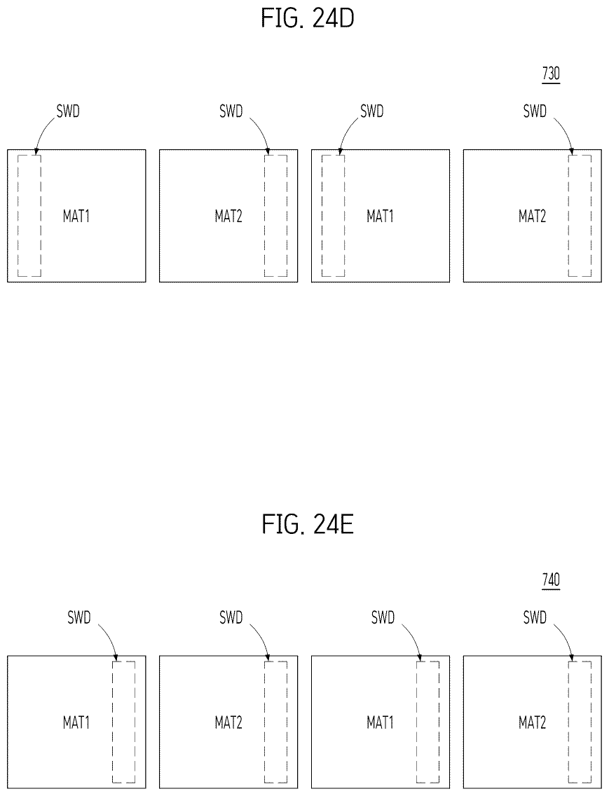

FIGS. 24A to 24E are diagrams illustrating a memory device in accordance with another embodiment of the present invention.

Referring to FIG. 24A, the memory device 700 may include a memory cell mat MAT1 and a peripheral circuit portion PRP. The memory cell mat MAT1 may be positioned above the peripheral circuit portion PRP. The memory cell mat MAT1 may include a plurality of sub word lines. For example, the memory cell mat MAT1 may include eight sub word lines SWL1 to SWL8. The sub word lines SWL1 to SWL8 may be individually formed of sub word lines that are stacked vertically, just as shown in FIG. 14A.

The peripheral circuit portion PRP may include at least one or more control circuits. The peripheral circuit portion PRP may include a sub word line driver circuit SWD. The sub word line driver circuit SWD may be positioned underneath one-side edge of the memory cell mat MAT1. The sub word line driver circuit SWD may not be positioned underneath the other-side edge of the memory cell mat MAT1.

The sub word line driver circuit SWD may be positioned underneath the one-side end of the memory cell mat MAT1. Herein, the one-side end of the memory cell mat MAT1 may be stepped ends of the sub word lines SWL1 to SWL8 on one side of the sub word lines SWL1 to SWL8. The sub word line driver circuit SWD may drive all of the sub word lines SWL1 to SWL8.

The sub word line driver circuit SWD may not be positioned underneath the stepped ends of the sub word lines SWL1 to SWL8 on another side.

Referring to FIG. 24B, the memory device 710 may include a plurality of memory cell mats MAT1 and MAT2. The memory cell mats MAT1 and MAT2 may be arranged in the row direction.

The sub word line driver circuit SWD may be positioned underneath the one-side ends of the memory cell mats MAT1 and MAT2. Herein, the one-side ends of the memory cell mats MAT1 and MAT2 may be stepped ends of the sub word lines SWL1 to SWL8. The sub word line driver circuit SWD may drive all of the sub word lines SWL1 to SWL8.

From the perspective of the memory cell mat MAT1, the sub word line driver circuit SWD may be positioned underneath the right side of the memory cell mat MAT1. The sub word line driver circuit SWD may not be positioned underneath the left side of the memory cell mat MAT1. From the perspective of the memory cell mat MAT2, the sub word line driver circuit SWD may be positioned underneath the right side of the memory cell mat MAT2. The sub word line driver circuit SWD may not be positioned underneath the left side of the memory cell mat MAT2.

Referring to FIG. 24C, the memory device 720 may include a plurality of memory cell mats MAT1 and MAT2. The memory cell mats MAT1 and MAT2 may be arranged in the row direction.

The sub word line driver circuit SWD may be positioned underneath the one-side ends of the memory cell mats MAT1 and MAT2. Herein, the one-side ends of the memory cell mats MAT1 and MAT2 may be stepped ends of the sub word lines SWL1 to SWL8 on one side. The sub word line driver circuit SWD may drive all of the sub word lines SWL1 to SWL8.

From the perspective of the memory cell mat MAT1, the sub word line driver circuit SWD may be positioned underneath the left side of the memory cell mat MAT1. The sub word line driver circuit SWD may not be positioned underneath the right side of the memory cell mat MAT1. From the perspective of the memory cell mat MAT2, the sub word line driver circuit SWD may be positioned underneath the right side of the memory cell mat MAT2. The sub word line driver circuit SWD may not be positioned underneath the left side of the memory cell mat MAT2.

Referring to FIG. 24D, the memory device 730 may include a plurality of memory cell mats MAT1 and MAT2. The memory cell mats MAT1 and MAT2 may be alternately arranged in the row direction.

The sub word line driver circuit SWD may be positioned underneath the one-side ends of the memory cell mats MAT1 and MAT2.

From the perspective of the memory cell mat MAT1, the sub word line driver circuit SWD may be positioned underneath the left side of the memory cell mat MAT1. The sub word line driver circuit SWD may not be positioned underneath the right side of the memory cell mat MAT1. From the perspective of the memory cell mat MAT2, the sub word line driver circuit SWD may be positioned underneath the right side of the memory cell mat MAT2. The sub word line driver circuit SWD may not be positioned underneath the left side of the memory cell mat MAT2.

Referring to FIG. 24E, the memory device 740 may include a plurality of memory cell mats MAT1 and MAT2. The memory cell mats MAT1 and MAT2 may be alternately arranged in the row direction.

The sub word line driver circuit SWD may be positioned underneath the one-side ends of the memory cell mats MAT1 and MAT2.

From the perspective of the memory cell mat MAT1, the sub word line driver circuit SWD may be positioned underneath the right side of the memory cell mat MAT1. The sub word line driver circuit SWD may not be positioned underneath the left side of the memory cell mat MAT1. From the perspective of the memory cell mat MAT2, the sub word line driver circuit SWD may be positioned underneath the right side of the memory cell mat MAT2. The sub word line driver circuit SWD may not be positioned underneath the left side of the memory cell mat MAT2.

Referring to FIGS. 24A to 24E, the net die may be increased by reducing the occupied area of the sub word line driver circuit SWD.

According to embodiments of the present invention, it is possible to increase cell density and to reduce parasitic capacitance by vertically stacking memory cells so as to form a three-dimensional structure.

According to embodiments of the present invention, interference between the vertically stacked memory cells may be prevented because a transistor of a memory cell includes double word lines.

According to embodiments of the present invention, since bit lines are formed as vertically oriented from a plane of a peripheral structure, bit line resistance may be reduced.

According to embodiments of the present invention, a memory device that is highly integrated within a limited area may be realized by vertically stacking memory cells in the upper or lower portion of a peripheral circuit portion.

According to embodiments of the present invention, the characteristic margin may be improved according to the increase in a transistor pitch by forming sub word line drivers underneath the memory cell mat.

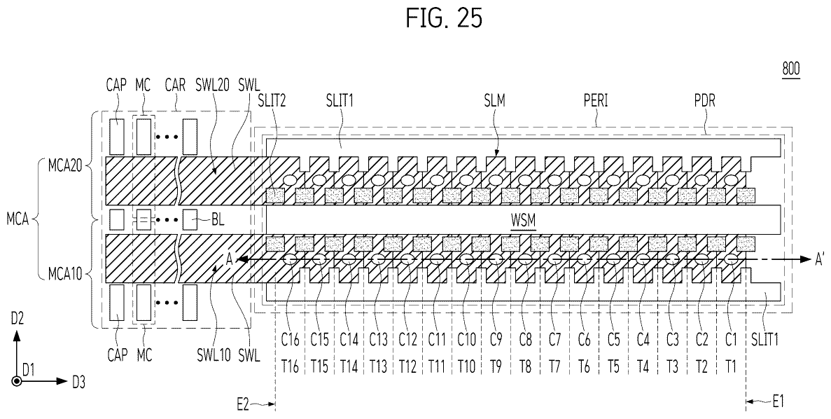

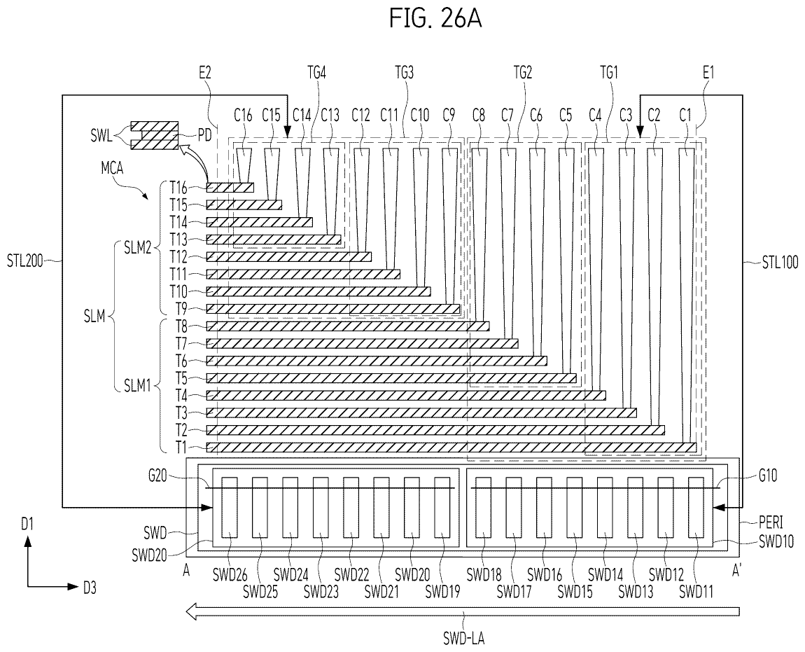

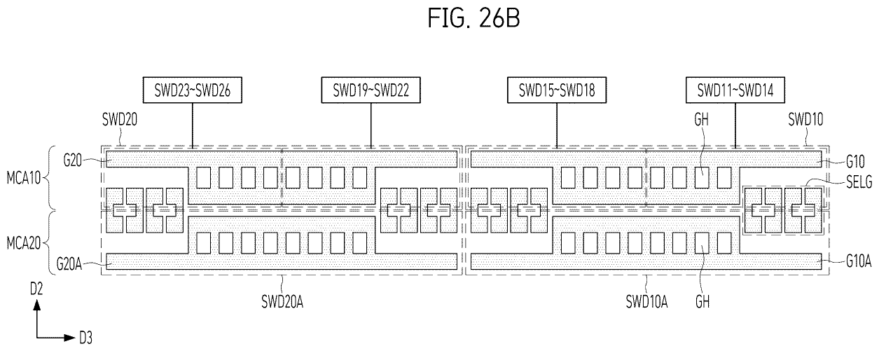

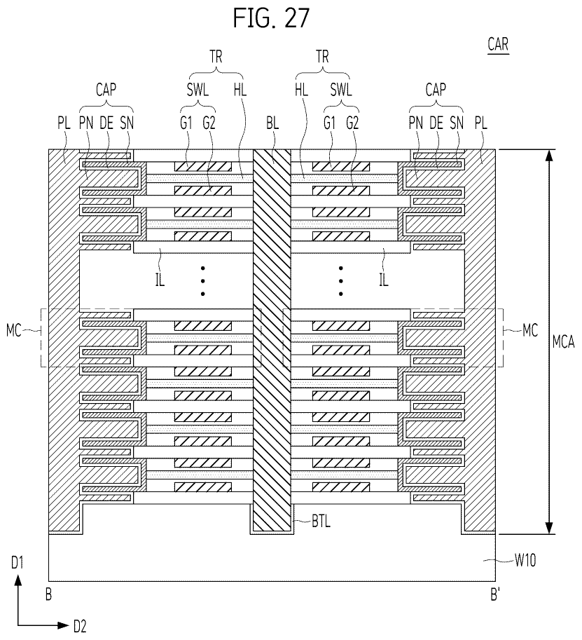

FIG. 25 is a schematic plan view illustrating a semiconductor device 800 according to an embodiment of the present invention. FIG. 26A is a schematic cross-sectional view of the semiconductor device 800 taken along line A-A′ of FIG. 25. FIG. 26B is a schematic view illustrating a sub-word line driver circuit of FIG. 26A. FIG. 27 is a schematic cross-sectional view of the semiconductor device 800 taken along line B-B′ of FIG. 25.

As illustrated in FIGS. 25 to 27, the semiconductor device 800 may include a memory cell array stack MCA and a peripheral circuit region PERI. The memory cell array stack MCA may include a cell array region CAR and a word line contact region PDR. The memory cell array stack MCA may include a plurality of memory cells MC. The cell array region CAR may include a vertical stack of memory cells MC. The word line contact region PDR may horizontally extend from the cell array region CAR. A detailed description of each of the memory cells MC is provided above with reference to FIGS. 1 to 11C. Each of the memory cells MC may include a bit line BL, a transistor TR, and a capacitor CAP. The transistor TR may include a horizontal layer HL and a word line SWL. The word line SWL may have a double structure. For example, the word line SWL may include an upper horizontal line G1 and a lower horizontal line G2 that face each other with a horizontal layer HL therebetween. The horizontal layer HL may correspond to the active layer ACT of FIG. 5. The upper horizontal line G1 may correspond to the upper word line G1 of FIG. 5. The lower horizontal line G2 may correspond to the lower word line G2 of FIG. 5. The capacitor CAP may include a first electrode SN, a dielectric layer DE, and a second electrode PN. The second electrodes PN of the capacitors CAP may be coupled to a common plate PL. Referring back to FIG. 27, the memory cell array stack MCA may be formed on a first substrate W10. A protective layer BTL may be formed on a bottom portion of the bit line BL of the memory cell array stack MCA. The memory cell array stack MCA may be a vertical stack of the memory cells MC stacked in a first direction D1. The vertical stack of memory cells MC may include a vertical stack of transistors TR and a vertical stack of capacitors CAP horizontally neighboring the vertical stack of transistors TR. In some embodiments, the vertical stack of memory cells MC may include a vertical stack of dynamic random access memory (DRAM) cells. In some embodiments, the word line SWL may have a gate all around structure (GAA). For example, the word line SWL may surround the horizontal layers HL disposed at the same horizontal level in the memory cell array stack MCA.

The memory cell array stack MCA may include first and second sub-memory cell arrays MCA10 and MCA20. The first and second sub-memory cell arrays MCA10 and MCA20 may each include the vertical stack of the memory cells MC stacked in the first direction D1. The memory cell array stack MCA may have a mirror-type structure of sharing the bit line BL. The first sub-memory cell array MCA10 and the second sub-memory cell array MCA20 may share the bit line BL. In the first sub-memory cell array MCA10, neighboring memory cells MC may share a first sub-word line stack SWL10, and in the second sub-memory cell array MCA20, neighboring memory cells MC may share a second sub-word line stack SWL20. The first and second sub-word line stacks SWL10 and SWL20 may refer to vertical stacks of word lines SWL. The word lines SWL may be referred to as ‘sub-word line’.

The memory cells MC may be formed in the cell array region CAR, and contact plugs C1 to C16 may be formed in the word line contact region PDR. The word line contact region PDR may be referred to as an open contact region (Open For Contact). Because contact plugs C1 to C16 are formed in the open contact region, the memory cells MC are not formed. A horizontal array of contact plugs C1 to C16 may be formed in the word line contact region PDR. A vertical stack of the memory cells MC may be formed in the cell array region CAR.

The first and second sub-word line stacks SWL10 and SWL20 may be disposed in the cell array region CAR, and pad stack structures SLM may be disposed in the word line contact region PDR. The pad stack structures SLM may extend from the first and second sub-word line stacks SWL10 and SWL20. The pad stack structures SLM may be referred to as a word line contact portion, a word line pad portion, or a sub-word line pad portion. A pad isolation structure WSM may be formed between the pad stack structures SLM in a second direction D2. The contact plugs C1 to C16 may be coupled to the pad stack structures SLM. The pad stack structures SLM may be coupled to the first and second sub-word line stacks SWL10 and SWL20. The pad stack structures SLM may refer to a vertical stack of a plurality of pad portions T1 to T16. Each of the pad portions T1 to T16 may include the word line SWL and a pad PD.

The pad stack structures SLM may include vertical stacks of the pad portions T1 to T16. Each of the pad stack structures SLM may include a step structure or a stair structure. The step structure of pad stack structures SLM may include steps defined at horizontal ends of the pad portions T1 to T16. Each of the pad stack structures SLM may include a first pad stack SLM1 and a second pad stack SLM2. The first pad stack SLM1 may be disposed at a lower level than the second pad stack SLM2. The first pad stack SLM1 may include a stack of the pad portions T1 to T8 of a first group, and the second pad stack SLM2 may include a stack of the pad portions T9 to T16 of a second group. In an embodiment, the first pad stack SLM1 and the second pad stack SLM2 may each include eight pad portions. The first pad stack SLM1 and the second pad stack SLM2 may each have a step structure or a stair structure.

In some embodiments, each of the pad stack structures SLM may include a step-less structure or a stair-less structure. The pad portions of the step-less structure have the same horizontal length. Contact plugs C1 to C16 may be coupled to the pad portions T1 to T16 without forming any stepped surfaces or staircase regions.

The pad portions T1 to T8 of the first group may be coupled to the contact plugs C1 to C8 of a first group, and the pad portions T9 to T16 of the second group may be coupled to the contact plugs C9 to C16 of a second group. The contact plugs C1 to C16 may have different vertical heights. In an embodiment, 16 contact plugs C1 to C16 and 16 pad portions T1 to T16 may be included.

The peripheral circuit region PERI may be disposed below the pad stack structures SLM. The peripheral circuit region PERI and the pad stack structures SLM may vertically overlap. The peripheral circuit region PERI may include a plurality of control circuits. For example, the peripheral circuit region PERI may include a sub-word line driver circuit SWD. The sub-word line driver circuit SWD may include first and second sub-word line driver circuits SWD10 and SWD20. The first sub-word line driver circuit SWD10 may be electrically coupled to the first pad stack SLM1, and the second sub-word line driver circuit SWD20 may be electrically coupled to the second pad stack SLM2. Detailed descriptions of the first and second sub-word line driver circuits SWD10 and SWD20 may be substituted with a description of the sub-word line driver circuit SWD with reference to FIGS. 17 and 18. The peripheral circuit region PERI may further include a sense amplifier.

The first sub-word line driver circuit SWD10 and the first pad stack SLM1 may be electrically coupled to each other through a multi-layer level interconnection STL100, and the second sub-word line driver circuit SWD20 and the second pad stack SLM2 may be electrically coupled to each other through a multi-layer level interconnection STL200. Detailed descriptions of the multi-layer level interconnections STL100 and STL200 are provided above with reference to FIGS. 19 to 20B.

Because the first pad stack SLM1 and the second pad stack SLM2 each include eight pad portions, the first and second sub-word line driver circuits SWD10 and SWD20 may each include eight sub-word line drivers. That is, 16 sub-word line drivers may be coupled to 16 pad portions T1 to T16.

In some embodiments, when a number of pad stacks of the pad stack structures SLM increases, the sub-word line driver circuits may be additionally disposed corresponding to the increased number of pad stacks. For example, when the pad stack structures SLM include a total of four pad stacks and each of the pad stacks includes eight pad portions, four sub-word line driver circuits may be disposed in the peripheral circuit region PERI, and each of the sub-word line driver circuits may include eight sub-word line drivers. Four sub-word line driver circuits may be disposed horizontally to each other below the pad stack structures SLM.

Referring to FIGS. 25 to 27, the semiconductor device 800 may include the memory cell array stack MCA including the pad stack structure SLM in which the plurality of pad portions T1 to T16 are vertically stacked, the peripheral circuit region PERI including the plurality of sub-word line driver circuits SWD10 and SWD20 vertically overlapping the pad stack structure SLM, the contact plugs C1 to C16 respectively coupled to the pad portions T1 to T16 of the pad stack structure SLM, and the interconnections STL100 and STL200 for coupling the contact plugs C1 to C16 to the sub-word line driver circuits SWD10 and SWD20. The sub-word line driver circuits SWD10 and SWD20 may be disposed horizontally to each other. Each of the sub-line driver circuits SWD10 and SWD20 may group and drive the pad portions T1 to T16. The vertical stack of the pad portions T1 to T16 may be grouped into a plurality of pad stacks, and the sub-word line driver circuits SWD10 and SWD20 may drive each of the pad stacks. For example, the 16 pad portions T1 to T16 may include first to fourth groups TG1 to TG4. The first group TG1 may include four pad portions T1 to T4, and the second group TG2 may include four pad portions T5 to T8. The third group TG3 may include four pad portions T9 to T12, and the fourth group TG4 may include four pad portions T13 to T16. The third group TG3 may be disposed at a lower level than the fourth group TG4, the second group TG2 may be disposed at a lower level than the third group TG3, and the first group TG1 may be disposed at a lower level than the second group TG2. The first sub-word line driver circuit SWD10 may include a horizontal array of eight sub-word line drivers SWD11 to SWD18 for driving the pad portions T1 to T8 of the first and second groups TG1 and TG2, and the second sub-word line driver circuit SWD20 may include a horizontal array of eight sub-word line drivers SWD19 to SWD26 for driving the pad portions T9 to T16 of the third and fourth groups TG3 and TG4.

Referring to FIG. 26B, the eight sub-word line drivers SWD11 to SWD18 of the first sub-word line driver circuit SWD10 may share a first common gate G10, and the eight sub-word line drivers SWD19 to SWD26 of the second sub-word line driver circuit SWD20 may share a second common gate G20. The first common gate G10 may correspond to the gate CG1 of FIG. 18, and the second common gate G20 may correspond to the gate CG2 of FIG. 18. The first common gate G10 and the second common gate G20 may be isolated from each other. The first and second common gates G10 and G20 may extend in the third direction D3. The sub-word line drivers SWD11 to SWD18 sharing the first common gate G10 may be horizontally disposed in the third direction D3. The sub-word line drivers SWD19 to SWD26 sharing the second common gate G20 may be horizontally disposed in the third direction D3. In this way, the sub-word line drivers SWD11 to SWD26 may be horizontally disposed in the third direction D3 in which the pad portions T1 to T16 extend. The first and second common gates G10 and G20 may include a plurality of hole-shape opening portions GH. The sub-word line drivers SWD11 to SWD26 may further include a plurality of selection gates SELG. The selection gates SELG may correspond to the selection gates G11, G12, G13, and G14 of FIG. 18.

The sub-word line driver circuits SWD10 and SWD20 may be coupled to the first sub-memory cell array MCA10, and the sub-word line driver circuits SWD10A and SWD20A may be coupled to the second sub-memory cell array MCA20. The sub-word line drivers of the sub-word line driver circuit SWD10A may share a common gate G10A, and the sub-word line drivers of the sub-word line driver circuit SWD20A may share a common gate G20A. The sub-word line driver circuit SWD10 and the sub-word line driver circuit SWD10A may be arranged horizontally to each other. The sub-word line driver circuit SWD20 and the sub-word line driver circuit SWD20A may be arranged horizontally to each other.

The pad portions T1 to T16 may be horizontally oriented in the third direction D3, and the sub-word line driver circuits SWD10 and SWD20 may be disposed parallel to the pad portions T1 to T16. The pad portions T1 to T16 may be vertically stacked in the first direction D1 from a lowermost pad portion T1 to an uppermost pad portion T16, and each of the pad portions T1 to T16 may horizontally extend in the third direction D3. The lowermost pad portion T1 has the longest horizontal length and the uppermost pad portion T16 has the shortest horizontal length. The pad portions T1 to T16 have different horizontal lengths.

The pad portions T1 to T16 may be horizontally oriented along the third direction D3, and the sub-word line drivers SWD10 and SWD20 may be disposed parallel to the pad portions T1 to T16. The pad portions T1 to T16 may be vertically stacked in the first direction D1 from the lowermost pad portion T1 to the uppermost pad portion T16, and each of the pad portions T1 to T16 may horizontally extend in the third direction D3. The sub-word line drivers SWD11 to SWD26 of the sub-word line driver circuits SWD10 and SWD20 may be horizontally disposed in the third direction D3 as indicated by reference symbol “SWD-LA”. The sub-word line driver SWD11 for driving the pad portion T1 may be disposed below a first part E1 of the pad stack structure SLM, and the sub-word line driver SWD26 for driving the pad portion T16 may be disposed below a second part E2 of the pad stack structure SLM. The second part E2 of the pad stack structure SLM may refer to a part closer to the cell array region CAR than the first part E1. The 16 sub-word line drivers SWD11 to SWD26 may be horizontally disposed in the third direction D3 from the first part E1 toward the second part E2 as indicated by reference symbol “SWD-LA”. The sub-word line driver SWD 26 is disposed closer to the cell array region CAR than the sub-word line driver SWD11. That is, as the number of pad portions in the pad stack structure SLM increases, the sub-word line drivers may be disposed closer to the cell array region CAR. In some embodiments, the sub-word line driver SWD11 for driving the pad portion T1 may be disposed below the second part E2 of the pad stack structure SLM, and the sub-word line driver SWD26 for driving the pad portion T16 may be disposed below the first part E1 of the pad stack structure SLM.

The sub-word line driver circuits SWD10 and SWD20 may control the pad portions T1 to T16 in a 1:8 coding scheme or a 1:16 coding scheme. That is, one sub-word line driver may be coupled to eight pad portions or 16 pad portions.

The sub-word line drivers SWD11 to SWD26 may include a plurality of transistors. The sub-word line drivers SWD11 to SWD26 may include a planar channel transistor, a recess channel transistor, a buried gate transistor, or a fin channel transistor (FinFET). The sub-word line drivers SWD11 to SWD26 may include a plurality of NMOSFET and a plurality of PMOSFET as described with reference to FIG. 17. An equivalent circuit of the sub-word line drivers SWD11 to SWD26 is described with reference to FIG. 17. In some embodiments, the layout of the sub-word line drivers SWD11 to SWD26 may be the same as that illustrated in FIG. 18.

As described above, the pad stack structure SLM in which the plurality of pad portions T1 to T16 are vertically stacked may vertically overlap with the sub-word line driver circuits SWD10 and SWD20. The sub-word line driver circuits SWD10 and SWD20 may include a plurality of sub-word line drivers SWD11 to SWD26 coupled to the pad portions T1 to T16. The sub-word line drivers SWD11 to SWD26 may be sequentially and horizontally disposed according to an increase in a number of layers of the pad portions T1 to T16. The common gates G10 and G20 and the pad portions T1 to T16 of the sub-word line driver circuits SWD10 and SWD20 may extend in the same direction, that is, in the third direction D3. The pad stack structure SLM may be stepped ends or a part of the memory cell mat. The pad stack structure SLM may correspond to the stepped ends of multi-level sub-word lines.

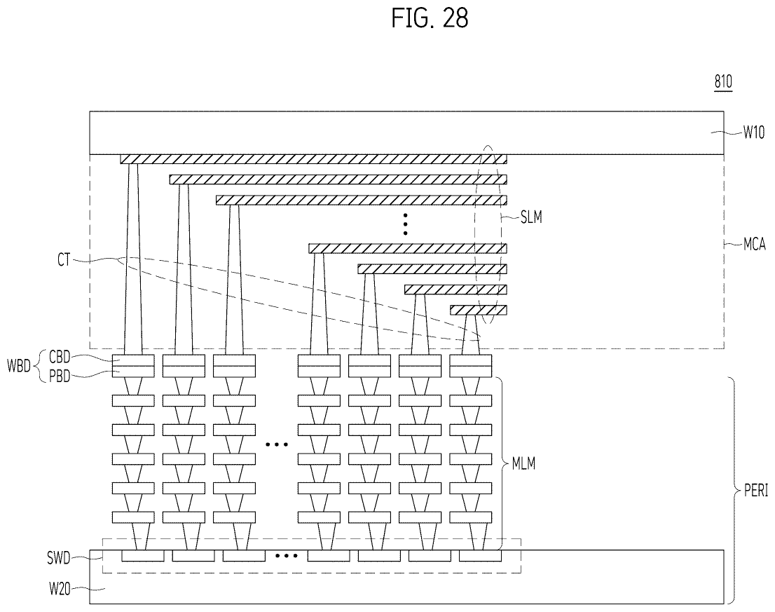

FIG. 28 is a schematic view illustrating a semiconductor device 810 according to an embodiment of the present invention.

Referring to FIG. 28, the semiconductor device 810 may include a memory cell array stack MCA, a peripheral circuit region PERI, and a bonding structure WBD between the memory cell array stack MCA and the peripheral circuit region PERI. The memory cell array stack MCA and the peripheral circuit region PERI may be coupled to each other through the bonding structure WBD. The bonding structure WBD may include a first bonding pad CBD coupled to the memory cell array stack MCA and a second bonding pad PBD coupled to the peripheral circuit region PERI. The memory cell array stack MCA and the peripheral circuit region PERI may be coupled to each other by a wafer bonding process. The memory cell array stack MCA may be disposed at a higher level than the peripheral circuit region PERI. This may be referred to as a Cell array Over PERI (COP) structure. The memory cell array stack MCA may be formed on a first substrate W10, and the peripheral circuit region PERI may include a second substrate W20. The peripheral circuit region PERI may include a plurality of control circuits and multi-layer level metal wiring MLM. For example, the control circuits may include a sub-word line driver circuit SWD. The sub-word line driver circuit SWD of the peripheral circuit region PERI and a pad stack structure SLM of the memory cell array stack MCA may be electrically coupled to each other through the multi-layer level metal wiring MLM, the second bonding pad PBD, the first bonding pad CBD and contact plugs CT. The multi-layer level metal wiring MLM may include the interconnections STL100 and STL 200 of FIG. 26.

For the wafer bonding process on the memory cell array stack MCA and the peripheral circuit region PERI, the first substrate W10 on which the memory cell array stack MCA and the first bonding pad CBD are formed may be flipped by a wafer flip.

Referring to FIG. 28, the semiconductor device 810 may include the memory cell array stack MCA including the pad stack structure SLM in which a plurality of pad portions are vertically stacked, the peripheral circuit region PERI including a plurality of sub-word line driver circuits SWD vertically overlapping the pad stack structure SLM, the contact plugs CT respectively coupled to the pad portions of the pad stack structure SLM, the multi-layer level metal wiring MLM coupled to the sub-word line driver circuit SWD, and the bonding structure WBD including the first bonding pads CBD coupled to the contact plugs CT and the second bonding pads PBD coupled to the multi-layer level metal wiring MLM. The sub-word line drivers of the sub-word line driver circuit SWD may be disposed horizontally to each other. Each of the sub-word line drivers of the sub-word line driver circuit SWD may group and drive the pad portions. A vertical stack of the pad portions may be grouped into a plurality of pad stacks, and the sub-word line drivers may drive each of the pad stacks. The pad portions may be horizontally oriented, and the sub-word line drivers may be disposed parallel to the pad portions. The sub-word line drivers may control the pad portions in a 1:8 coding scheme or a 1:16 coding scheme. That is, one sub-word line driver may be coupled to eight pad portions or 16 pad portions. In some embodiments, the bonding structure WBD may include pad bonding, hybrid bonding, oxide-to-oxide bonding, metal-to-metal bonding, or a combination thereof. The hybrid bonding may refer to a combination of the pad bonding and the oxide-to-oxide bonding.

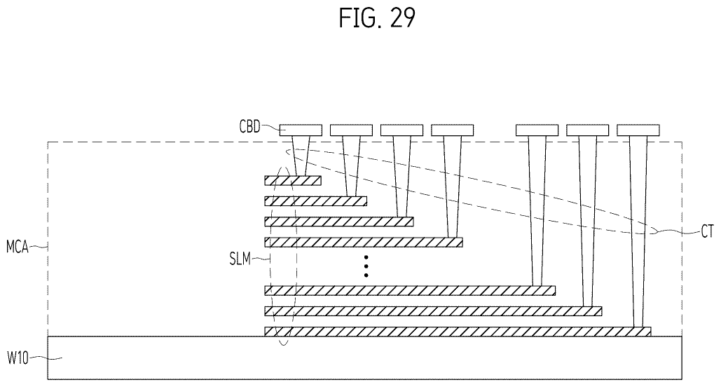

FIGS. 29 to 31 are views illustrating an example of a method of fabricating the semiconductor device 810 shown in FIG. 28.

As illustrated in FIG. 29, the memory cell array stack MCA may be formed on a first substrate W10. The first substrate W10 may be a material suitable for semiconductor processing. The first substrate W10 may include at least one of a conductive material, a dielectric material and a semiconductive material. The first substrate W10 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The first substrate W10 may also include another semiconductive material such as germanium. The first substrate W10 may also include a III-V group semiconductor substrate, for example, a compound semiconductor substrate such as GaAs. The first substrate W10 may include a Silicon On Insulator (SOI) substrate.

The memory cell array stack MCA may include the pad stack structures SLM each having a step-type structure. The pad stack structures SLM may each include a vertical stack of the pad portions. A detailed description of the memory cell array stack MCA is provided above with reference to FIGS. 25 to 27. As such, the memory cell array stack MCA may include the vertical stack of the pad portions.

Subsequently, the contact plugs CT coupled to the pad structures SLM may be formed.

Subsequently, the first bonding pads CBD coupled to the contact plugs CT may be formed.

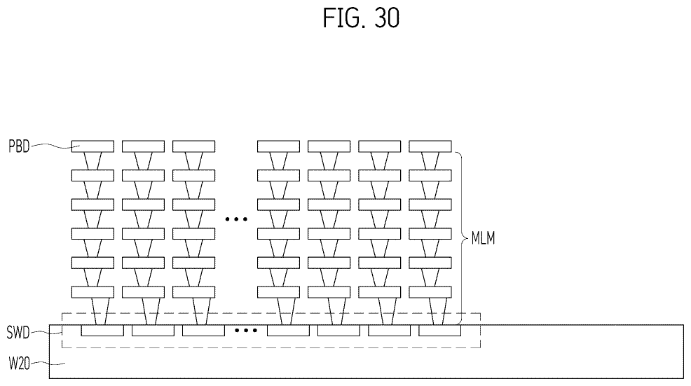

As illustrated in FIG. 30, a plurality of control circuits including the sub-word line driver circuit SWD may be formed on a second substrate W20.

The second substrate W20 may include at least one of a conductive material, a dielectric material and a semiconductive material. The second substrate W20 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The second substrate W20 may also include another semiconductive material such as germanium. The second substrate W20 may also include a III-V group semiconductor substrate, for example, a compound semiconductor substrate such as GaAs. The second substrate W20 may include a Silicon On Insulator (SOI) substrate.

Subsequently, the multi-layer level metal wiring MLM coupled to the sub-word line driver circuit SWD may be formed. The multi-layer level metal wiring MLM may include a plurality of metal contact plugs or vias and a plurality of metal lines.

Subsequently, the second bonding pads PBD may be formed on the multi-layer level metal wiring MLM.

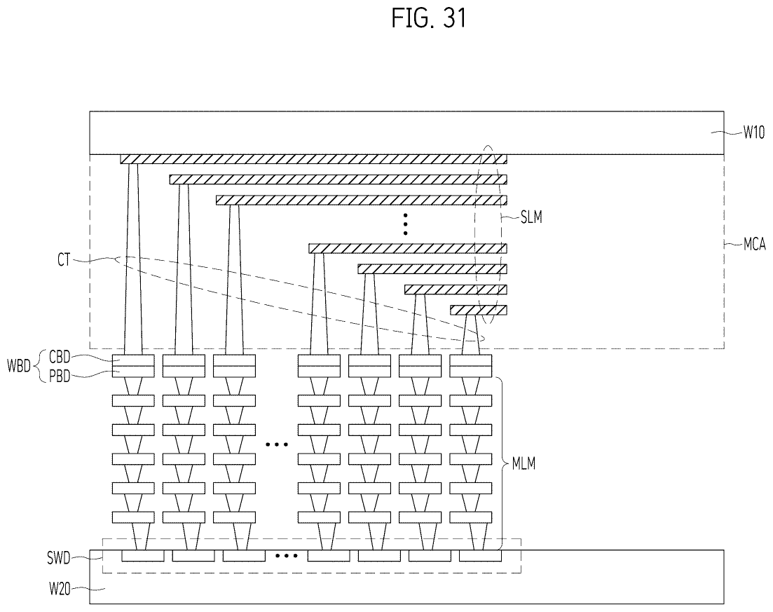

As illustrated in FIG. 31, the first substrate W10 may be flipped. For example, the first substrate W10 may be flipped by the wafer flip so that a back side of the first substrate W10 is disposed at a higher level than a front side of the first substrate W10. The first bonding pad CBD may be disposed at a lower level than the memory cell array stack MCA by the wafer flip. In some embodiments, after the wafer flip, back grinding such as CMP may be performed to reduce a thickness of the back side of the first substrate W10.

Subsequently, the wafer bonding process may be performed for electrical coupling between the memory cell array stack MCA and the sub-word line driver circuit SWD. For example, the wafer bonding process may be performed on the first substrate W10 and the second substrate W20 so that the first bonding pad CBD and the second bonding pad PBD may be bonded. In some embodiments, the wafer bonding process may include pad bonding, hybrid bonding, oxide-to-oxide bonding, metal-to-metal bonding, or a combination thereof. The hybrid bonding may refer to a combination of the pad bonding and the oxide-to-oxide bonding.

Referring to FIGS. 29 to 31, a method of fabricating the semiconductor device may include forming the memory cell array stack MCA including the vertical stack of the pad portions over the first substrate W10, forming the first bonding pads CBD respectively coupled to the pad portions in the vertical stack, forming the control circuits including a plurality of sub-word line drivers over the second substrate W20, forming the multi-layer level metal wiring MLM coupled to the sub-word line drivers, forming the second bonding pads PBD coupled to the multi-layer level metal wiring MLM, and performing the wafer bonding process for electrical coupling between the memory cell array stack MCA and the control circuits.

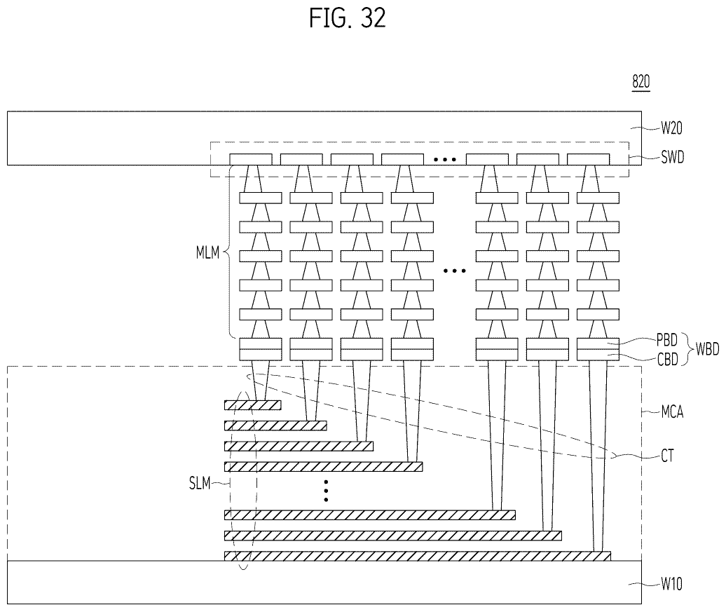

FIG. 32 is a schematic view illustrating a semiconductor device 820 according to an embodiment of the present invention.

As illustrated in FIG. 32, the semiconductor device 820 may include a memory cell array stack MCA, a peripheral circuit region PERI, and a bonding structure WBD between the memory cell array stack MCA and the peripheral circuit region PERI. The memory cell array stack MCA and the peripheral circuit region PERI may be coupled to each other through the bonding structure WBD. The bonding structure WBD may include a first bonding pad CBD coupled to the memory cell array stack MCA and a second bonding pad PBD coupled to the peripheral circuit region PERI. The memory cell array stack MCA and the peripheral circuit region PERI may be coupled to each other by a wafer bonding process. The memory cell array stack MCA may be disposed at a lower level than the peripheral circuit region PERI. This may be referred to as a PERI Over Cell array (POC) structure. The memory cell array stack MCA may be formed on a first substrate W10, and the peripheral circuit region PERI may include a second substrate W20. The peripheral circuit region PERI may include a plurality of control circuits and multi-layer level metal wiring MLM. For example, the control circuits may each include a sub-word line driver circuit SWD. The sub-word line driver circuit SWD of the peripheral circuit region PERI and a pad stack structure SLM of the memory cell array stack MCA may be electrically coupled to each other through the multi-layer level wiring MLM, the second bonding pad PBD, the first bonding pad CBD and contact plugs CT.

The second substrate W20 on which the sub-word line driver circuit SWD, the multi-level metal wiring MLM and the second bonding pad PBD are formed may be flipped by a wafer flip for wafer bonding of the memory cell array stack MCA and the peripheral circuit region PERI.

As described above, because a sub-word line driver circuit is disposed below pad stack structures, structural stability of a 3D DRAM may increase.

In addition, because a word line contact region PDR of an open contact region OFC is formed, a burden due to an increase in a number layers of pad portions may be reduced.

While the present invention has been described with respect to specific embodiments, it will be apparent to those skilled in the art that various changes and modifications may be made without departing from the spirit and scope of the invention as defined in the following claims.

What is claimed is:

1. A method of fabricating a semiconductor device, the method comprising:
forming a memory cell array stack including a vertical stack of pad portions over a first substrate;
forming first bonding pads coupled to the pad portions in the vertical stack;
forming control circuits including a plurality of sub-word line drivers over a second substrate;
forming multi-layer level metal wiring coupled to the sub-word line drivers;
forming second bonding pads coupled to the multi-layer level metal wiring; and
performing a wafer bonding process for electrical coupling between the memory cell array stack and the control circuits.

2. The method of claim 1, wherein the sub-word line drivers are horizontally disposed on the second substrate.

3. The method of claim 1, wherein each of the sub-word line drivers groups and drives the pad portions.

4. The method of claim 1, wherein the vertical stack of the pad portions is grouped into a plurality of pad stacks, and the sub-word line drivers drive each of the pad stacks.

5. The method of claim 1, wherein the pad portions are horizontally oriented along a horizontal direction, and the sub-word line drivers are arranged along the horizontal direction.

6. The method of claim 1, wherein the vertical stack of pad portions includes steps defined at horizontal ends of the pad portions.

7. The method of claim 1, wherein the sub-word line drivers share a common gate, and the common gate and the pad portions extend horizontally along the same direction.

8. The method of claim 1, wherein the forming of the memory cell array stack includes forming a 3D array of a plurality of memory cells vertically stacked over the first substrate.

9. The method of claim 8, wherein each of the memory cells includes:
a vertically-oriented bit line;
a plurality of capacitors stacked vertically; and
transistors disposed between the bit line and the capacitors.

10. The method of claim 9, wherein each of the transistors includes:
a horizontal layer horizontally oriented from the bit line; and
a word line having a double structure of crossing the horizontal layer while overlapping the horizontal layer.

11. The method of claim 1, wherein the performing of the wafer bonding process includes performing a wafer flip on the first substrate so that the first bonding pads and the second bonding pads face each other.

12. A semiconductor device comprising:
a memory cell array stack including a vertical stack of memory cells and a vertical stack of pad portions;
a peripheral circuit region including a horizontal array of sub-word line drivers vertically overlapping the vertical stack of pad portions;
contact plugs coupled to the pad portions;
multi-layer level metal wiring coupled to the sub-word line drivers; and
a bonding structure including first bonding pads coupled to the contact plugs and second bonding pads coupled to the multi-layer level metal wiring.

13. The semiconductor device of claim 12, wherein the sub-word line drivers are horizontally disposed to each other.

14. The semiconductor device of claim 12, wherein the vertical stack of pad portions is grouped into plurality of pad stacks, and the sub-word line drivers drive each of the pad stacks.

15. The semiconductor device of claim 12, wherein the pad portions are horizontally oriented along a horizontal direction, and the sub-word line drivers are arranged along the horizontal direction.

16. The semiconductor device of claim 12, wherein the vertical stack of memory cells comprising:
a vertical stack of transistors; and
a vertical stack of capacitors horizontally neighboring the vertical stack of transistors.

17. The semiconductor device of claim 12, wherein the vertical stack of pad portions includes steps defined at horizontal ends of the pad portions.

18. The semiconductor device of claim 12, wherein the horizontal array of sub-word line drivers shares a common gate, and the common gate and the pad portions extend horizontally along the same direction.

19. The semiconductor device of claim 12, wherein each of the memory cells includes:
a vertically-oriented bit line;
a plurality of capacitors stacked vertically; and
transistors disposed between the bit line and the capacitors.

20. The semiconductor device of claim 12, wherein the memory cell array stack is disposed at a higher level or a lower level than the peripheral circuit region.
